(19) United States
(12) Patent Application Publication
(10) Pub. No.: US 2025/0385224 A1
(43) Pub. Date: Dec. 18, 2025

(54) SEMICONDUCTOR MODULE

(71) Applicant: ROHM CO., LTD., Kyoto (JP)

(72) Inventors: Shinji YATO, Kyoto (JP); Hideo ARAKI, Kyoto (JP); Hiroto SAKAI, Kyoto (JP); Yuta OKAWAUCHI, Kyoto (JP)

(21) Appl. No.: 19/233,203

(22) Filed: Jun. 10, 2025

(30) Foreign Application Priority Data
Jun. 17, 2024 (JP) 2024-097518

(51) Int. Cl. H01L 25/07; H01L 23/00; H03K 17/56

(52) U.S. Cl. CPC H01L 25/072; H01L 24/48; H01L 2224/48137; H03K 17/56

(57) ABSTRACT

A semiconductor module includes: a first transistor and a second transistor connected in parallel to each other, wherein a parallel resonant circuit of the first transistor and the second transistor has a first pole frequency (ωₚ₁), a second pole frequency (ωₚ₂) higher than the first pole frequency (ωₚ₁), and a zero frequency (ω_{z}), and wherein an absolute value of a phase lag between the second pole frequency (ωₚ₂) and the zero frequency (ω_{z}) is set to be smaller than 180 degrees.

### CROSS-REFERENCE TO RELATED APPLICATION

This application is based upon and claims the benefit of priority from Japanese Patent Application No. 2024-097518, filed on Jun. 17, 2024, the entire contents of which are incorporated herein by reference.

### TECHNICAL FIELD

The present disclosure relates to a semiconductor module.

### BACKGROUND

In the related art, a power module in which a half-bridge circuit is constituted by a plurality of first switching elements and a plurality of second switching elements is disclosed. The plurality of first switching elements are connected in parallel to each other. The plurality of second switching elements are connected in parallel to each other.

### BRIEF DESCRIPTION OF DRAWINGS

The accompanying drawings, which are incorporated in and constitute a part of the specification, illustrate embodiments of the present disclosure.

FIG. 1 is a schematic plan view showing an internal configuration of an exemplary semiconductor module according to a first embodiment of the present disclosure.

FIG. 2 is a schematic cross-sectional view of the semiconductor module cut along line F2-F2 in FIG. 1.

FIG. 3 is a schematic cross-sectional view of the semiconductor module cut along line F3-F3 in FIG. 1.

FIG. 4 is a schematic equivalent circuit diagram of the semiconductor module of FIG. 1.

FIG. 5 is a schematic circuit diagram showing an inductance component between a first transistor and a second transistor connected in parallel in the semiconductor module of FIG. 1.

FIG. 6 is an equivalent circuit diagram of parallel oscillation in the semiconductor module of FIG. 1.

FIG. 7 is a Bode diagram showing a relationship between gain and frequency in the equivalent circuit diagram of FIG. 6.

FIG. 8 is a Bode diagram showing a relationship between phase and frequency in the equivalent circuit diagram of FIG. 6.

FIG. 9 is a schematic plan view of a semiconductor module simplified for evaluation of the semiconductor module of FIG. 1.

FIG. 10 is a schematic equivalent circuit diagram of the semiconductor module of FIG. 9.

FIG. 11 is a graph showing transition of a gate-source voltage at turn-off in the semiconductor module of FIG. 9 when a ratio (ωₚ₂/ω_{z}) of a second pole frequency ωₚ₂ to a zero frequency ωz is 0.3.

FIG. 12 is a graph showing transition of a gate-source voltage at turn-off in the semiconductor module of FIG. 9 when the ratio (ωₚ₂/ω_{z}) is 0.375.

FIG. 13 is a graph showing transition of a gate-source voltage at turn-off in the semiconductor module of FIG. 9 when the ratio (ωₚ₂/ω_{z}) is 0.55.

FIG. 14 is a schematic plan view of an illustrative semiconductor module according to a second embodiment of the present disclosure.

FIG. 15 is a schematic circuit diagram of the semiconductor module of FIG. 14.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, some embodiments of a semiconductor module according to the present disclosure will be described with reference to the accompanying drawings. It should be noted that, for simplicity and clarity of explanation, constituent elements shown in the drawings are not necessarily drawn to scale. Further, in order to facilitate understanding, hatching lines may be omitted in cross-sectional views. The accompanying drawings merely illustrate embodiments of the present disclosure and should not be considered as limiting the present disclosure.

The following detailed description includes devices, systems, and methods embodying exemplary embodiments of the present disclosure. This detailed description is for illustrative purposes only and is not intended to limit the embodiments of the present disclosure or the applications and uses of such embodiments.

The expression “at least one” as used in the present disclosure means “one or more” of desired options. As an example, in a case where there are two options, the expression “at least one” as used in the present disclosure means “only one option” or “both of the two options.” As another example, in a case where there are three or more options, the expression “at least one” as used in the present disclosure means “only one option” or “any combination of two or more options.”

As used in the present disclosure, “a dimension (a width or a length) of A is equal to a dimension (a width or a length) of B” or “a dimension (a width or a length) of A and a dimension (a width or a length) of B are equal to each other” also includes a relationship in which a difference between the dimension (the width or the length) of A and the dimension (the width or the length) of B is within, for example, 10% of the dimension (the width or the length) of A.

### First Embodiment

### [Schematic Configuration of Semiconductor Module]

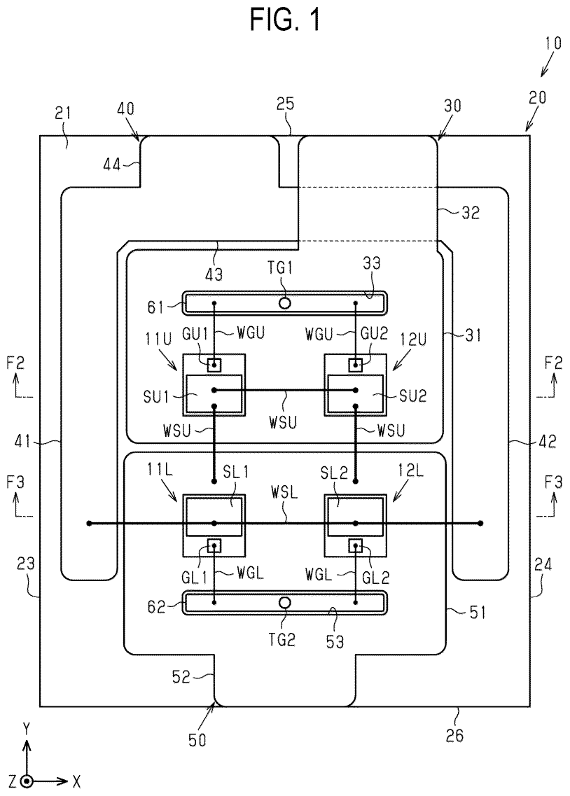

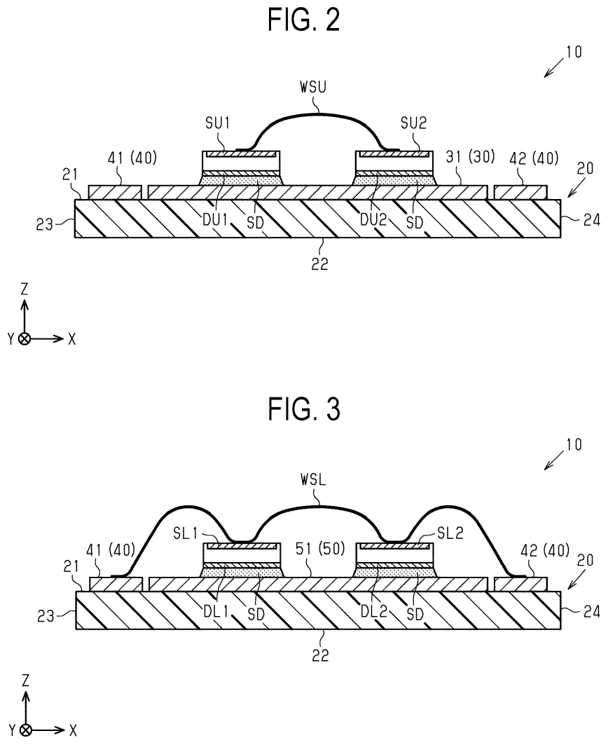

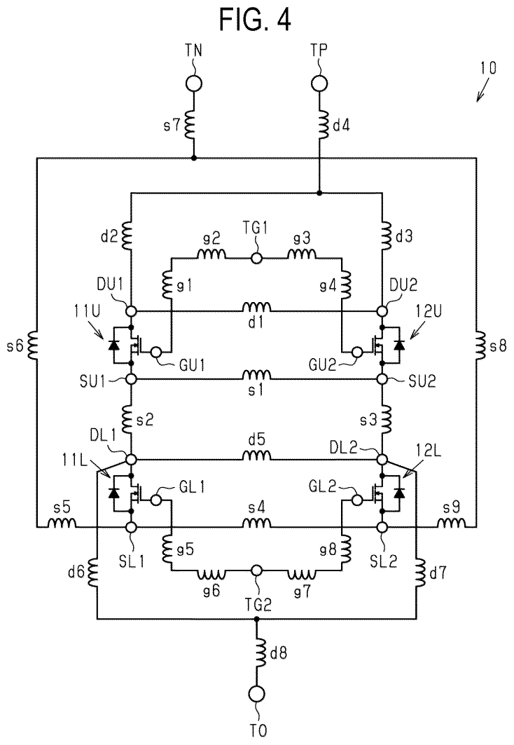

FIGS. 1 to 4 show an exemplary configuration of a semiconductor module 10 according to a first embodiment of the present disclosure. FIG. 1 shows a schematic planar structure of the semiconductor module 10. FIG. 2 shows a schematic cross-sectional structure of the semiconductor module 10 cut along line F2-F2 in FIG. 1. FIG. 3 shows a schematic cross-sectional structure of the semiconductor module 10 cut along line F3-F3 in FIG. 1. FIG. 4 is a circuit diagram showing inductance components of the semiconductor module 10.

As shown in FIG. 1, the semiconductor module 10 includes a first upper arm transistor 11U, a second upper arm transistor 12U, a first lower arm transistor 11L, and a second lower arm transistor 12L. The first upper arm transistor 11U and the second upper arm transistor 12U are connected in parallel to each other. The first lower arm transistor 11L and the second lower arm transistor 12L are connected in parallel to each other. The first upper arm transistor 11U and the second upper arm transistor 12U are connected in series with the first lower arm transistor 11L and the second lower arm transistor 12L. In other words, the semiconductor module 10 includes a half-bridge circuit constituted by the upper arm transistors 11U and 12U and the lower arm transistors 11L and 12L. In this case, the first lower arm transistor 11L is an example of a “first transistor,” and the second lower arm transistor 12L is an example of a “second transistor.”

Each of the transistors 11U, 11L, 12U, and 12L may be, for example, a silicon carbide (SiC) metal-oxide-semiconductor field-effect-transistor (MOSFET). Each of the transistors 11U, 11L, 12U, and 12L may be a SiMOSFET, an insulated gate bipolar transistor (IGBT), or a gallium nitride (GaN) transistor, instead of the SiCMOSFET.

As shown in FIGS. 1 to 3, each of the transistors 11U, 11L, 12U, and 12L has a flat plate shape with its thickness direction in a Z direction. Each of the transistors 11U, 11L, 12U, and 12L includes a first element surface and a second element surface on an opposite side to the first element surface. The first upper arm transistor 11U includes a first gate electrode GU1 and a first source electrode SU1 provided on the first element surface, and a first drain electrode DU1 provided on the second element surface. The second upper arm transistor 12U includes a second gate electrode GU2 and a second source electrode SU2 provided on the first element surface, and a second drain electrode DU2 provided on the second element surface. The first lower arm transistor 11L includes a first gate electrode GL1 and a first source electrode SL1 provided on the first element surface, and a first drain electrode DL1 provided on the second element surface. The second lower arm transistor 12L includes a second gate electrode GL2 and a second source electrode SL2 provided on the first element surface, and a second drain electrode DL2 provided on the second element surface.

The semiconductor module 10 includes a substrate 20 having a flat plate shape with its thickness direction in the Z direction. In an example, the substrate 20 has a rectangular shape with its short side direction in an X direction and its long side direction in a Y direction when viewed from the Z direction. The substrate 20 includes a first substrate surface 21 on which the transistors 11U, 11L, 12U, and 12L are mounted, and a second substrate surface 22 on an opposite side to the first substrate surface 21. The substrate 20 includes first to fourth substrate side surfaces 23 to 26 as four substrate side surfaces that connect the first substrate surface 21 and the second substrate surface 22. The first substrate side surface 23 and the second substrate side surface 24 constitute both end surfaces of the substrate 20 in the X direction. The third substrate side surface 25 and the fourth substrate side surface 26 constitute both end surfaces of the substrate 20 in the Y direction. For example, a glass epoxy substrate may be used for the substrate 20. Note that the substrate 20 may be a substrate having a higher heat dissipation performance than a glass epoxy substrate such as alumina. Further, a shape of the substrate 20 in a plan view may be changed arbitrarily.

The semiconductor module 10 includes a first power supply wiring 30, a second power supply wiring 40, an output wiring 50, a first gate wiring 61, and a second gate wiring 62, which are provided on the first substrate surface 21. The first power supply wiring 30, the second power supply wiring 40, the output wiring 50, the first gate wiring 61, and the second gate wiring 62 are made of a conductive material such as aluminum (Al), copper (Cu), or silver (Ag). In an example, each of the first power supply wiring 30, the second power supply wiring 40, the output wiring 50, the first gate wiring 61, and the second gate wiring 62 is made of a conductive material containing Cu.

Herein, the first power supply wiring 30 is an example of a “drain wiring” corresponding to each of the upper arm transistors 11U and 12U, the output wiring 50 is an example of a “source wiring” corresponding to each of the upper arm transistors 11U and 12U, and the first gate wiring 61 is an example of a “gate wiring” corresponding to each of the upper arm transistors 11U and 12U. In addition, the output wiring 50 is an example of a “drain wiring” corresponding to each of the lower arm transistors 11L and 12L, the second power supply wiring 40 is an example of a “source wiring” corresponding to each of the lower arm transistors 11L and 12L, and the second gate wiring 62 is an example of a “gate wiring” corresponding to each of the lower arm transistors 11L and 12L.

The first power supply wiring 30 and the output wiring 50 are disposed side by side in the Y direction. The first power supply wiring 30 is disposed to be closer to the third substrate side surface 25 than the output wiring 50. The first power supply wiring 30 constitutes an input wiring of an inverter circuit of the semiconductor module 10. The first power supply wiring 30 is a wiring electrically connected to a positive electrode of a DC power supply (not shown). Therefore, a current is supplied from the DC power supply to the first power supply wiring 30. The first upper arm transistor 11U and the second upper arm transistor 12U are mounted on the first power supply wiring 30. More specifically, both of the first upper arm transistor 11U and the second upper arm transistor 12U are bonded to the first power supply wiring 30 by a conductive bonding material SD. As a result, both of the first drain electrode DU1 of the first upper arm transistor 11U and the second drain electrode DU2 of the second upper arm transistor 12U are electrically connected to the first power supply wiring 30.

The first power supply wiring 30 includes an element mounting portion 31 on which the transistors 11U and 12U are mounted, and a terminal connection portion 32 extending from the element mounting portion 31 toward the third substrate side surface 25 when viewed from the Z direction.

The element mounting portion 31 has a rectangular shape with its long sides in the X direction and its short sides in the Y direction when viewed from the Z direction. The first upper arm transistor 11U and the second upper arm transistor 12U are disposed at the same position in the Y direction and spaced apart from each other in the X direction. An opening 33 is provided at a portion of the element mounting portion 31 closer to the third substrate side surface 25 than the transistors 11U and 12U. The first gate wiring 61 is provided within the opening 33 when viewed from the Z direction. The first gate wiring 61 is disposed to be spaced apart from the element mounting portion 31. The first gate wiring 61 has a strip shape extending in the X direction when viewed from the Z direction. The first gate wiring 61 is provided to face the transistors 11U and 12U in the Y direction when viewed from the Z direction. A shape of the element mounting portion 31 when viewed from the Z direction may be changed as desired.

The first gate electrode GU1 of the first upper arm transistor 11U and the second gate electrode GU2 of the second upper arm transistor 12U are electrically connected to the first gate wiring 61 by a gate wire WGU. A first gate terminal TG1 is provided at the center of the first gate wiring 61 in the X direction. Therefore, both of the first gate electrode GU1 and the second gate electrode GU2 are electrically connected to the first gate terminal TG1 via the gate wire WGU and the first gate wiring 61.

Herein, the gate wire WGU connected to the first gate electrode GU1 is an example of a “first gate connection member” corresponding to the first upper arm transistor 11U, and the gate wire WGU connected to the second gate electrode GU2 is an example of a “second gate connection member” corresponding to the second upper arm transistor 12U.

The terminal connection portion 32 is provided in the element mounting portion 31, closer to the second substrate side surface 24. The terminal connection portion 32 is provided to be spaced apart from the first substrate surface 21 of the substrate 20 in the Z direction. In an example, the terminal connection portion 32 is provided integrally with the element mounting portion 31. A power supply terminal TP (see FIG. 4) is connected to the terminal connection portion 32. Although not shown in FIG. 1, the power supply terminal TP is provided so as to protrude from the third substrate side surface 25 of the substrate 20 in the Y direction when viewed from the Z direction. The power supply terminal TP constitutes an external terminal that is electrically connected to an external electronic device when the semiconductor module 10 is mounted on the electronic device.

The output wiring 50 constitutes an output wiring of an inverter circuit of the semiconductor module 10. The first lower arm transistor 11L and the second lower arm transistor 12L are mounted on the output wiring 50. More specifically, both of the first lower arm transistor 11L and the second lower arm transistor 12L are bonded to the output wiring 50 by a conductive bonding material SD. As a result, both of the first drain electrode DL1 of the first lower arm transistor 11L and the second drain electrode DL2 of the second lower arm transistor 12L are electrically connected to the output wiring 50.

The first source electrode SU1 of the first upper arm transistor 11U and the second source electrode SU2 of the second upper arm transistor 12U are each electrically connected to the output wiring 50 by a source wire WSU. In addition, the first source electrode SU1 and the second source electrode SU2 are electrically connected to each other by another source wire WSU. Therefore, both of the first source electrode SU1 and the second source electrode SU2 are electrically connected to the first drain electrode DL1 of the first lower arm transistor 11L and the second drain electrode DL2 of the second lower arm transistor 12L via the output wiring 50. Here, the source wire WSU is an example of a “source connection member” corresponding to each of the upper arm transistors 11U and 12U.

The output wiring 50 includes an element mounting portion 51 on which the transistors 11L and 12L are mounted, and a terminal connection portion 52 extending from the element mounting portion 51 toward the fourth substrate side surface 26 when viewed from the Z direction.

The element mounting portion 51 has a rectangular shape with its long sides in the X direction and its short sides in the Y direction when viewed from the Z direction. The element mounting portion 51 is disposed side by side with the element mounting portion 31 of the first power supply wiring 30 in the Y direction. The first lower arm transistor 11L and the second lower arm transistor 12L are disposed at the same position in the Y direction and spaced apart from each other in the X direction. An opening 53 is provided in a portion of the element mounting portion 51 closer to the fourth substrate side surface 26 than the transistors 11L and 12L. The second gate wiring 62 is provided within the opening 53 when viewed from the Z direction. The second gate wiring 62 is disposed to be spaced apart from the element mounting portion 51. The second gate wiring 62 has a strip shape extending in the X direction when viewed from the Z direction. The second gate wiring 62 is provided to face the transistors 11L and 12L in the Y direction when viewed from the Z direction. A shape of the element mounting portion 51 when viewed from the Z direction may be changed as desired.

The first gate electrode GL1 of the first lower arm transistor 11L and the second gate electrode GL2 of the second lower arm transistor 12L are electrically connected to the second gate wiring 62 by a gate wire WGL. A second gate terminal TG2 is provided at the center of the second gate wiring 62 in the X direction. Therefore, both of the first gate electrode GL1 and the second gate electrode GL2 are electrically connected to the second gate terminal TG2 via the gate wire WGL and the second gate wiring 62. In this case, the gate wire WGL connected to the first gate electrode GL1 is an example of a “first gate connection member” corresponding to the first lower arm transistor 11L, and the gate wire WGL connected to the second gate electrode GL2 is an example of a “second gate connection member” corresponding to the second lower arm transistor 12L.

The terminal connection portion 52 extends from a center of the element mounting portion 51 in the X direction toward the fourth substrate side surface 26 when viewed from the Z direction. The terminal connection portion 52 is provided integrally with the element mounting portion 51. An output terminal TO (see FIG. 4) is connected to the terminal connection portion 52. Although not shown in FIG. 1, the output terminal TO is provided so as to protrude from the fourth substrate side surface 26 of the substrate 20 in the Y direction when viewed from the Z direction. The output terminal TO constitutes an external terminal that is electrically connected to an external electronic device when the semiconductor module 10 is mounted on the electronic device.

The second power supply wiring 40 constitutes a ground wiring of the inverter circuit of the semiconductor module 10. The second power supply wiring 40 is provided so as to surround the element mounting portion 31 of the first power supply wiring 30 from both sides in the X direction and from a side of the third substrate side surface 25 in the Y direction when viewed from the Z direction. The second power supply wiring 40 includes a first connection wiring 41, a second connection wiring 42, a linking wiring 43, and a terminal connection portion 44. Here, the first connection wiring 41 is an example of a “first wiring portion” corresponding to each of the lower arm transistors 11L and 12L, and the second connection wiring 42 is an example of a “second wiring portion” corresponding to each of the lower arm transistors 11L and 12L.

The first connection wiring 41 is disposed to be closer to the first substrate side surface 23 than the element mounting portion 31. The first connection wiring 41 has a strip shape extending in the Y direction. The first connection wiring 41 extends to a position facing the element mounting portion 51 of the output wiring 50 when viewed from the X direction.

The second connection wiring 42 is disposed to be closer to the second substrate side surface 24 than the element mounting portion 31. The second connection wiring 42 has a strip shape extending in the Y direction. The second connection wiring 42 extends to a position facing the element mounting portion 51 of the output wiring 50 when viewed from the X direction.

The linking wiring 43 is a wire linking the first connection wire 41 and the second connection wire 42. The linking wiring 43 is disposed to be closer to the third substrate side surface 25 than the element mounting portion 31. The linking wiring 43 has a strip shape extending in the X direction. The linking wiring 43 includes a portion that overlaps with the terminal connection portion 32 of the first power supply wire 30 when viewed from the Z direction. The linking wiring 43 is disposed to be closer to the first substrate surface 21 than the terminal connection portion 32 in the Z direction.

The terminal connection portion 44 extends from the linking wiring 43 toward the third substrate side surface 25. The terminal connection portion 44 is disposed side by side with the terminal connection portion 32 of the first power supply wire 30 in the X direction when viewed from the Z direction. The terminal connection portion 44 is disposed to be closer to the first substrate side surface 23 than the terminal connection portion 32. A ground terminal TN (see FIG. 4) is connected to the terminal connection portion 44. Although not shown in FIG. 1, the ground terminal TN is provided so as to protrude from the third substrate side surface 25 of the substrate 20 in the Y direction when viewed from the Z direction. The ground terminal TN constitutes an external terminal that is electrically connected to an external electronic device when the semiconductor module 10 is mounted on the electronic device.

The first source electrode SL1 of the first lower arm transistor 11L and the second source electrode SL2 of the second lower arm transistor 12L are each electrically connected to the second power supply wiring 40 by a source wire WSL. More specifically, both of the first source electrode SL1 and the second source electrode SL2 are connected to both the first connection wiring 41 and the second connection wiring 42 of the second power supply wiring 40 by the source wire WSL. The source wire WSL extends in the X direction when viewed from the Z direction, and is connected to the first connection wiring 41, the first source electrode SL1, the second source electrode SL2, and the second connection wiring 42. Here, the source wire WSL is an example of a “source connection member” corresponding to each of the lower arm transistors 11L and 12L.

FIG. 4 is a schematic equivalent circuit diagram of the semiconductor module 10 showing inductance components of conductive paths in the semiconductor module 10. The inductance components of the conductive paths include inductance components due to wirings and wires. More specifically, the semiconductor module 10 includes first to ninth source inductances s1 to s9, first to seventh drain inductances d1 to d8, and first to eighth gate inductances g1 to g8. In the following description, the components of the semiconductor module 10 refer to the components of the semiconductor module 10 shown in FIGS. 1 to 3.

The first source inductance s1 indicates an inductance component of the source wire WSU connecting the first source electrode SU1 of the first upper arm transistor 11U and the second source electrode SU2 of the second upper arm transistor 12U. The second source inductance s2 indicates an inductance component of the conductive path between the first source electrode SU1 and the first drain electrode DL1 of the first lower arm transistor 11L. This inductance component indicates a sum of an inductance component of the source wire WSU connecting the first source electrode SU1 of the first upper arm transistor 11U and the output wiring 50, and an inductance component of the conductive path between the source wire WSU of the output wiring 50 and the first drain electrode DL1 of the first lower arm transistor 11L. A third source inductance s3 indicates a sum of an inductance component of the source wire WSU connecting the second source electrode SU2 and the output wiring 50, and an inductance component of the conductive path between the source wire WSU of the output wiring 50 and the second drain electrode DL2 of the second lower arm transistor 12L.

The fourth source inductance s4, the fifth source inductance s5, and the ninth source inductance s9 indicate inductance components of the source wire WSL connecting the first source electrode SL1 of the first lower arm transistor 11L, the second source electrode SL2 of the second lower arm transistor 12L, and the first connection wiring 41 and the second connection wiring 42 of the second power supply wiring 40. More specifically, the fourth source inductance s4 indicates an inductance component of a portion of the source wire WSL that connects the first source electrode SL1 and the second source electrode SL2. The fifth source inductance s5 indicates an inductance component of a portion of the source wire WSL that connects the first source electrode SL1 and the first connection wiring 41. The ninth source inductance s9 indicates an inductance component of a portion of the source wire WSL that connects the second source electrode SL2 and the second connection wiring 42.

The sixth source inductance s6, the seventh source inductance s7, and the eighth source inductance s8 indicate inductance components of the second power supply wiring 40. The sixth source inductance s6 indicates a sum of an inductance component of the first connection wiring 41 of the second power supply wiring 40 and an inductance component of the conductive path between the first connection wiring 41 and the terminal connection portion 44 of the linking wiring 43. The seventh source inductance s7 indicates an inductance component of the terminal connection portion 44. The eighth source inductance s8 indicates a sum of an inductance component of the second connection wiring 42 of the second power supply wiring 40 and an inductance component of the conductive path between the second connection wiring 42 and the terminal connection portion 44 of the linking wiring 43.

The first drain inductance d1 indicates an inductance component of the conductive path connecting the first drain electrode DU1 of the first upper arm transistor 11U and the second drain electrode DU2 of the second upper arm transistor 12U of the element mounting portion 31 of the first power supply wiring 30. The second drain inductance d2 indicates an inductance component of the conductive path between the first drain electrode DU1 and the terminal connection portion 32 of the element mounting portion 31. The third drain inductance d3 indicates an inductance component of the conductive path between the second drain electrode DU2 and the terminal connection portion 32 of the element mounting portion 31. The fourth drain inductance d4 indicates an inductance component of the terminal connection portion 32.

The fifth drain inductance d5 indicates an inductance component of the conductive path between the first drain electrode DL1 of the first lower arm transistor 11L and the second drain electrode DL2 of the second lower arm transistor 12L of the element mounting portion 51 of the output wiring 50. The sixth drain inductance d6 indicates an inductance component of the conductive path between the first drain electrode DL1 and the terminal connection portion 52 of the element mounting portion 51. The seventh drain inductance d7 indicates an inductance component of the conductive path between the second drain electrode DL2 and the terminal connection portion 52 of the element mounting portion 51. The eighth drain inductance d8 indicates an inductance component of the terminal connection portion 52.

The first gate inductance g1 indicates an inductance component of the gate wire WGU that connects the first gate electrode GU1 of the first upper arm transistor 11U and the first gate wiring 61. The second gate inductance g2 indicates an inductance component of a portion of the first gate wiring 61 between the gate wire WGU and the first gate terminal TG1. The fourth gate inductance g4 indicates an inductance component of the gate wire WGU that connects the second gate electrode GU2 of the second upper arm transistor 12U and the first gate wiring 61. The third gate inductance g3 indicates an inductance component of a portion of the first gate wiring 61 between the gate wire WGU connected to the second gate electrode GU2 and the first gate terminal TG1.

The fifth gate inductance g5 indicates an inductance component of the gate wire WGL that connects the first gate electrode GL1 of the first lower arm transistor 11L and the second gate wiring 62. The sixth gate inductance g6 indicates an inductance component of a portion of the second gate wiring 62 between the gate wire WGL and the second gate terminal TG2. The eighth gate inductance g8 indicates an inductance component of the gate wire WGL that connects the second gate electrode GL2 of the second lower arm transistor 12L and the second gate wiring 62. The seventh gate inductance g7 indicates an inductance component of a portion of the second gate wiring 62 between the gate wire WGL connected to the second gate electrode GL2 and the second gate terminal TG2.

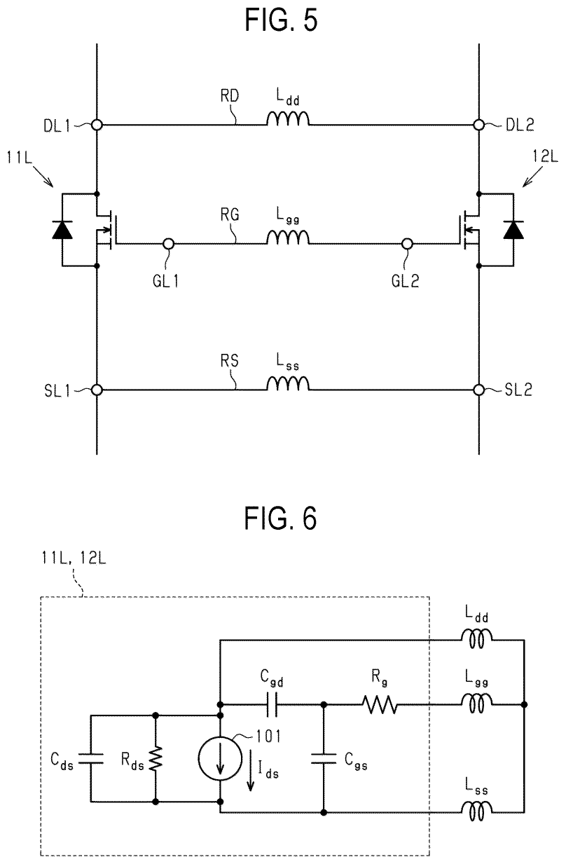

FIG. 5 shows a schematic equivalent circuit showing an inductance component between the first lower arm transistor 11L and the second lower arm transistor 12L connected in parallel in the semiconductor module 10 shown in FIG. 4.

The semiconductor module 10 includes a drain conductive path RD that electrically connects the first drain electrode DL1 and the second drain electrode DL2, a source conductive path RS that electrically connects the first source electrode SL1 and the second source electrode SL2, and a gate conductive path RG that electrically connects the first gate electrode GL1 and the second gate electrode GL2. The drain conductive path RD includes a drain inductance L_{dd} as a parasitic inductance of the drain conductive path RD. The source conductive path RS includes a source inductance Lₛₛ as a parasitic inductance of the source conductive path RS. The gate conductive path RG includes a gate inductance L_{gg} as a parasitic inductance of the gate conductive path RG.

For example, the gate inductance L_{gg} is a sum (g5+g6+g7+g8) of the fifth to eighth gate inductances g5 to g8. The source inductance Lₛₛ is a combined inductance (s4//(s5+s6+s8+s9)) of the fourth source inductance s4 and the fifth, sixth, eighth, and ninth source inductances s5, s6, s8, and s9 in parallel. This combined inductance Lₛₛ may also be expressed as Lₛₛ=s4·(s5+s6+s8+s9)/(s4+s5+s6+s8+s9). The drain inductance L_{dd} is a combined inductance (d5//(s1+s2+s3)) of the fifth drain inductance d5 and the first to third source inductances s1 to s3 in parallel. This combined inductance L_{dd} may also be expressed as L_{dd}=d5·(s1+s2+s3)/(d5+s1+s2+s3).

FIG. 6 shows an equivalent circuit of parallel oscillation in the semiconductor module 10 shown in FIG. 5. In the semiconductor module 10 shown in FIG. 6, a parasitic resistance component and a parasitic capacitance component of the first lower arm transistor 11L or the second lower arm transistor 12L are shown as an example. Note that in the semiconductor module 10, parallel oscillation may also occur in the first upper arm transistor 11U and the second upper arm transistor 12U. For this reason, the equivalent circuit of parallel oscillation in the semiconductor module 10 may be shown by a parasitic resistance component and a parasitic capacitance component of the first upper arm transistor 11U or the second upper arm transistor 12U. In the following, the parasitic resistance component and parasitic capacitance component of the first lower arm transistor 11L or the second lower arm transistor 12L will be used for explanation.

The semiconductor module 10 includes a drain-source resistance R_{ds} and a gate resistance R_{g} as parasitic resistance components of the first lower arm transistor 11L or the second lower arm transistor 12L. The semiconductor module 10 includes a drain-source capacitance C_{ds}, a gate-drain capacitance C_{gd}, and a gate-source capacitance C_{gs} as parasitic capacitance components of the first lower arm transistor 11L or the second lower arm transistor 12L.

The semiconductor module 10 also includes a current source 101. The current source 101 is configured to supply a drain-source current I_{ds} based on a gate-source voltage V_{gs_i}. In FIG. 6, a mutual conductance of the first lower arm transistor 11L or the second lower arm transistor 12L is set as a “mutual conductance gₘ.” In this case, the drain-source current I_{ds} supplied by the current source 101 is set by multiplying the mutual conductance gₘ by the gate-source voltage V_{gs_i} (that is, I_{ds}=gₘ·V_{gs_i}).

As shown in FIG. 6, the drain-source resistance R_{d}s, the drain-source capacitance C_{ds}, and the gate-source capacitance C_{gs} are connected in parallel to the current source 101. The gate resistance R_{g} and the gate-drain capacitance C_{gd} are connected in series. A first terminal of the gate-source capacitance C_{gs} is electrically connected to a first terminal of the gate resistance R_{g} which is connected to the gate-drain capacitance C_{gd}. A second terminal of the gate-source capacitance C_{gs} is electrically connected to the source inductance Lₛₛ. In other words, the gate-source capacitance C_{gs} is electrically connected to the source of the first lower arm transistor 11L or the second lower arm transistor 12L. A second terminal of the gate resistance R_{g} is electrically connected to the gate inductance L_{gg}. The drain inductance L_{dd} is electrically connected to the drain-source capacitance C_{ds}, the drain-source resistance R_{ds}, and the gate-drain capacitance C_{gd}. In this way, the drain-source capacitance C_{ds}, the drain-source resistance R_{ds}, and the gate-drain capacitance C_{gd} are electrically connected to the drain of the first lower arm transistor 11L or the second lower arm transistor 12L.

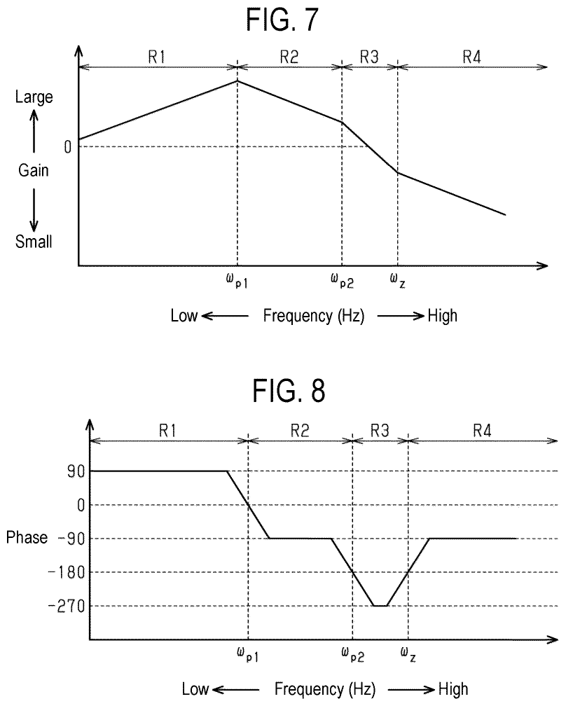

In the semiconductor module 10 shown in FIG. 6, in a case where the terminal voltage of the gate-source capacitance C_{gs} is a gate-source voltage V_{gs_o}, open loop characteristics from the gate-source voltage V_{gs_i} to the gate-source voltage V_{gs_o} are shown by Bode diagrams of FIGS. 7 and 8. Here, the open loop characteristics include gain characteristics and phase characteristics. Further, the gate-source voltage V_{gs_i} indicates a voltage input to the current source 101. The gate-source voltage V_{gs_o} indicates a voltage generated by propagation of an output current of the current source 101.

FIG. 7 is a graph showing a relationship between frequency (Hz) and gain. FIG. 8 is a graph showing a relationship between frequency (Hz) and phase. The phase in FIG. 8 is a phase difference between the gate-source voltage V_{gs_i} and the gate-source voltage V_{gs_o}.

As shown in FIGS. 7 and 8, the open loop characteristics may be divided into first to fourth regions R1 to R4 as a frequency range. These first to fourth regions R1 to R4 are divided by a first pole frequency ωₚ₁, a second pole frequency ωₚ₂, and a zero frequency ωz. More specifically, the first region R1 is a region less than the first pole frequency ωₚ₁. The second region R2 is a region equal to or greater than the first pole frequency ωₚ₁ and less than the second pole frequency ωₚ₂. The third region R3 is a region equal to or greater than the second pole frequency ωₚ₂ and equal to or less than the zero frequency ω_{z}. The fourth region R4 is a region greater than the zero frequency ω_{z}. Here, each of the first pole frequency ωₚ₁, the second pole frequency ωₚ₂, and the zero frequency ω_{z} indicates a frequency at an inflection point of the gain characteristics shown in FIG. 7.

As shown in FIG. 7, the first region R1 is a region where the gain increases as the frequency approaches the first pole frequency ωₚ₁. The second region R2 is a region where the gain decreases as the frequency goes from the first pole frequency ωₚ₁ to the second pole frequency ωₚ₂. In other words, the first pole frequency ωₚ₁ is a frequency where the gain changes from increasing to decreasing. The third region R3 is a region where the gain decreases as the frequency approaches from the second pole frequency ωₚ₂ to the zero frequency ω_{z}. A degree of gain decrease in the third region R3 is greater than a degree of gain decrease in the second region R2. In other words, the second pole frequency ωₚ₂ is a frequency where the degree of gain decrease changes. The fourth region R4 is a region where the gain decreases as the frequency increases from the zero frequency ω_{z}. A degree of gain decrease in the fourth region R4 is smaller than the degree of gain decrease in the third region R3. In other words, the zero frequency ω_{z} is a frequency where the degree of gain decrease changes.

As shown in FIG. 8, the phase is positive in the first region R1 and negative in the second to fourth regions R2 to R4. When the phase is negative, it can be said that a phase lag occurs. The phase becomes zero at the first pole frequency ωₚ₁. In both of the second region R2 and the fourth region R4, the phase becomes negative (phase lag), but its absolute value is smaller than 180 degrees. On the other hand, in the third region R3, the absolute value of the phase lag becomes larger than 180 degrees. In other words, the absolute value of the phase lag becomes larger than 180 degrees at a frequency where the gain becomes zero. Here, in the example of FIG. 8, the absolute value of the phase lag is 180 degrees at the second pole frequency ωₚ₂ and the zero frequency ω_{z}.

A transfer function G(s) of the parallel resonant circuit shown in FIG. 6 can be expressed by the following equation.

$$G ( s ) \approx \frac{K {ω}_{p 1}^{2} {ω}_{p 2}^{2}}{{ω}_{z}^{2}} \cdot \frac{s ( {s}^{2} + 2 {ζ}_{z} {ω}_{z} s + {ω}_{z}^{2} )}{( {s}^{2} + 2 {ζ}_{p 1} {ω}_{p 1} s + {ω}_{p 1}^{2} ) ( {s}^{2} + 2 {ζ}_{p 2} {ω}_{p 2} s + {ω}_{p 2}^{2} )} \qquad [ Eq . 1 ]$$

Here, “K” is a differential coefficient, and “ζₚ₁,” “ζₚ₂,” and “ζ_{z}” are a first pole damping coefficient, a second pole damping coefficient, and a zero damping coefficient, respectively. Further, “s” is a Laplace operator.

Additionally, the first pole frequency ωₚ₁, the second pole frequency ωₚ₂, and the zero frequency ω_{z} can be expressed by the following equations. The first pole damping coefficient ζₚ₁, the second pole damping coefficient ζₚ₂, and the zero damping coefficient ζ_{z} can be expressed by the following equations.

$${ω}_{p 1} \approx \frac{1}{\sqrt{( {L}_{gg} + {L}_{ss} ) {C}_{gs}}} \qquad [ Eq . 2 ]$$

$${ω}_{p 2} \approx \frac{1}{\sqrt{( {L}_{dd} + {L}_{gg} / {L}_{ss} ) {C}_{ds}}} \qquad [ Eq . 3 ]$$

$${ω}_{z} \approx \frac{1}{\sqrt{( {L}_{dd} + {L}_{gg} ) {C}_{gd}}} \qquad [ Eq . 4 ]$$

$${ζ}_{p 1} \approx \frac{{R}_{g}}{2} \sqrt{\frac{{C}_{gs}}{{L}_{gg} + {L}_{ss}}} \qquad [ Eq . 5 ]$$

$${ζ}_{p 2} \approx \frac{1}{2 {R}_{ds}} \sqrt{\frac{{L}_{dd} + {L}_{ss} / {L}_{gg}}{{C}_{ds}}} \qquad [ Eq . 6 ]$$

$${ζ}_{z} \approx \frac{{R}_{g}}{2} \sqrt{\frac{{C}_{gd}}{{L}_{dd} + {L}_{gg}}} \qquad [ Eq . 7 ]$$

Here, L_{gg}//Lₛₛ in Eq. 3 indicates L_{gg}·Lₛₛ/(L_{gg}+Lₛₛ). Lₛₛ//L_{gg} in Eq. 6 indicates Lₛₛ·L_{gg}/(Lₛₛ+L_{gg}). Based on the above, the first pole frequency ωₚ₁, the second pole frequency ωₚ₂, and the zero frequency ω_{z} can be calculated.

In the open loop characteristics shown in FIGS. 7 and 8, as described above, in a case where the gain becomes zero or more when the absolute value of the phase lag becomes 180 degrees or more in the third region R3, the first lower arm transistor 11L and the second lower arm transistor 12L oscillate in parallel in the third region R3. For this reason, parallel oscillation can be suppressed by making the third region R3 smaller. In other words, in order to suppress the parallel oscillation, the second pole frequency ωₚ₂ and the zero frequency ω_{z} may be made to be close to each other. Based on this viewpoint, a relationship between the second pole frequency ωₚ₂ and the zero frequency ω_{z} can be expressed by the following equation from the above equations.

$$\frac{{ω}_{p 2}}{{ω}_{z}} = \sqrt{\frac{{C}_{gd}}{{C}_{ds}}} \times \sqrt{\frac{α}{β + γ + 1} + 1} ( α = \frac{{L}_{gg}}{{L}_{ss}} , β = \frac{{L}_{dd}}{{L}_{ss}} , γ = \frac{{L}_{dd}}{{L}_{gg}} ) \qquad [ Eq . 8 ]$$

As a ratio (ωₚ₂/ω_{z}) of the second pole frequency ωₚ₂ to the zero frequency ω_{z} in Eq. 8 approaches 1, the third region R3 becomes smaller. On the other hand, even in a case where the third region R3 does not disappear completely, the parallel oscillation can be suppressed as long as the absolute value of the phase lag at the second pole frequency ωₚ₂ and the zero frequency ω_{z} is smaller than 180 degrees.

### (Simulation of Parallel Oscillation)

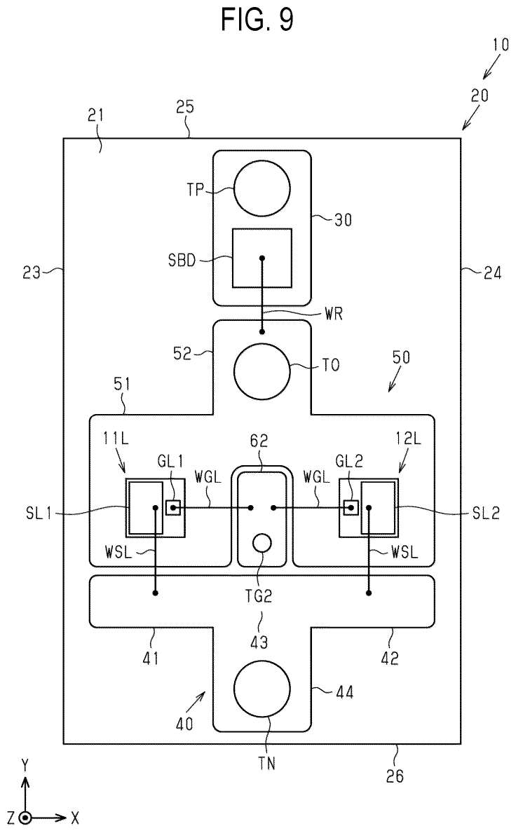

FIGS. 9 to 13 show a simulation model and its results for the ratio (ωp2/ωz) that can suppress the parallel oscillation. FIG. 9 is a simulation model of the semiconductor module 10.

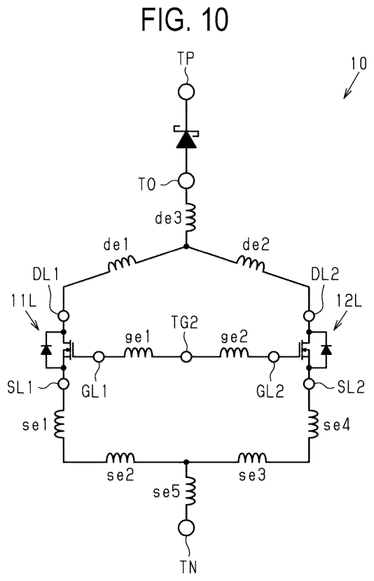

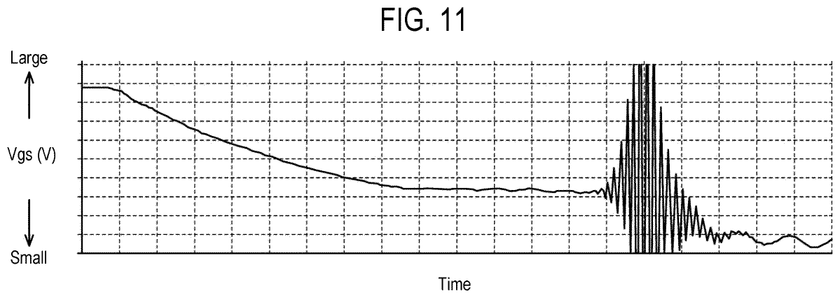

FIG. 10 shows a relationship among inductances of the semiconductor module 10 shown in FIG. 9. FIGS. 11 to 13 show transition of a gate-source voltage V_{gs} when the ratio (ωₚ₂/ω_{z}) is changed.

The semiconductor module 10 shown in FIGS. 9 and 10 is a simulation model that simplifies the configuration of the semiconductor module 10 shown in FIGS. 1 and 4 for evaluation of the ratio (ωₚ₂/ω_{z}) that can suppress the parallel oscillation.

FIG. 9 is a model for evaluating the configuration related to the first lower arm transistor 11L and the second lower arm transistor 12L shown in FIG. 1. In switching of the first lower arm transistor 11L and the second lower arm transistor 12L, the first upper arm transistor 11U and the second upper arm transistor 12U (see also FIG. 1) perform a rectifying operation. For this reason, as shown in FIG. 9, the first upper arm transistor 11U and the second upper arm transistor 12U connected in parallel in the semiconductor module 10 are shown as a Schottky barrier diode SBD. An anode of the Schottky barrier diode SBD is electrically connected to the output wiring 50 by a wire WR. A cathode of the Schottky barrier diode SBD is electrically connected to the first power supply wiring 30. Accordingly, a shape of the first power supply wiring 30 is also simplified. In addition, the first gate wiring 61 (see FIG. 1) is omitted.

The shapes of the second power supply wiring 40 and the output wiring 50 are also changed. The second power supply wiring 40 is formed in a T-shape when viewed from the Z direction. The second power supply wiring 40 is disposed side by side with the output wiring 50 in the Y direction. The second power supply wiring 40 is disposed on the opposite side of the output wiring 50 from the first power supply wiring 30 in the Y direction.

In the output wiring 50, the shape of the element mounting portion 51 is different so that the second gate wiring 62 is disposed between the first lower arm transistor 11L and the second lower arm transistor 12L in the X direction. Each of the transistors 11L and 12L is mounted on the element mounting portion 51 in such a direction that each of the gate electrodes GL1 and GL2 are located near the second gate wiring 62.

The terminal connection portion 52 of the output wiring 50 is disposed side by side with the first power supply wiring 30 in the Y direction. The wire WR connected to the anode of the Schottky barrier diode SBD is connected to the terminal connection portion 52. The output terminal TO is also connected to the terminal connection portion 52.

The first connection wiring 41 of the second power supply wiring 40 is disposed at the same position as the first lower arm transistor 11L in the X direction. The second connection wiring 42 is disposed at the same position as the second lower arm transistor 12L in the X direction. These connection wirings 41 and 42 extend in the X direction when viewed from the Z direction. The linking wiring 43 is provided between the first connection wiring 41 and the second connection wiring 42 in the X direction. The terminal connection portion 44 extends from the linking wiring 43 toward the fourth substrate side surface 26. The terminal connection portion 44 is connected to the ground terminal TN.

As shown in FIG. 10, the conductive path of the first lower arm transistor 11L and the second lower arm transistor 12L connected in parallel in the semiconductor module 10 includes first to third drain inductances de1 to de3, first to fifth source inductances se1 to se5, a first gate inductance ge1, and a second gate inductance ge2. In the following, components of the semiconductor module 10 refer to the components of the semiconductor module 10 shown in FIG. 9.

The first drain inductance de1 indicates an inductance component of the conductive path between the first drain electrode DL1 of the first lower arm transistor 11L in the element mounting portion 51 and the terminal connection portion 52. The second drain inductance de2 indicates an inductance component of the conductive path between the second drain electrode DL2 of the second lower arm transistor 12L in the element mounting portion 51 and the terminal connection portion 52. The third drain inductance de3 indicates an inductance component of the terminal connection portion 52.

The first source inductance se1 indicates an inductance component of the source wire WSL that connects the first source electrode SL1 of the first lower arm transistor 11L and the first connection wiring 41 of the second power supply wiring 40. The second source inductance se2 indicates an inductance component of the conductive path between the source wire WSL in the first connection wiring 41 and the linking wiring 43 and the terminal connection portion 44. The fourth source inductance se4 indicates an inductance component of the source wire WSL that connects the second source electrode SL2 of the second lower arm transistor 12L and the second connection wiring 42. The third source inductance se3 indicates an inductance component of the conductive path between the source wire WSL connected to the second connection wiring 42 in the second connection wiring 42 and the linking wiring 43 and the terminal connection portion 44. The fifth source inductance se5 indicates an inductance component of the terminal connection portion 44.

The first gate inductance ge1 indicates an inductance component of the gate wire WGL that connects the first gate electrode GL1 of the first lower arm transistor 11L and the second gate wiring 62. The second gate inductance ge2 indicates an inductance component of the gate wire WGL that connects the second gate electrode GL2 of the second lower arm transistor 12L and the second gate wiring 62. Note that an inductance component of the second gate wiring 62 is assumed to be negligibly small as compared to the gate inductances ge1 and ge2.

Next, results of simulation in which the ratio (ωₚ₂/ω_{z}) shown in FIGS. 11 to 13 is changed will be described. The gate-source voltage V_{gs} of the first lower arm transistor 11L and the gate-source voltage V_{gs} of the second lower arm transistor 12L fluctuate in the same manner, although there is a phase shift. For this reason, FIGS. 11 to 13 show the transition of the gate-source voltage V_{gs} of the first lower arm transistor 11L.

FIG. 11 shows the transition of the gate-source voltage V_{gs} when each of the transistors 11L and 12L is turned off in a case where the ratio (ωₚ₂/ω_{z}) is 0.3. As can be seen from FIG. 11, the gate-source voltage V_{gs} of the first lower arm transistor 11L oscillates abnormally. For this reason, when the ratio (ωₚ₂/ω_{z}) is 0.3, very large parallel oscillation occurs when each of the transistors 11L and 12L is turned off.

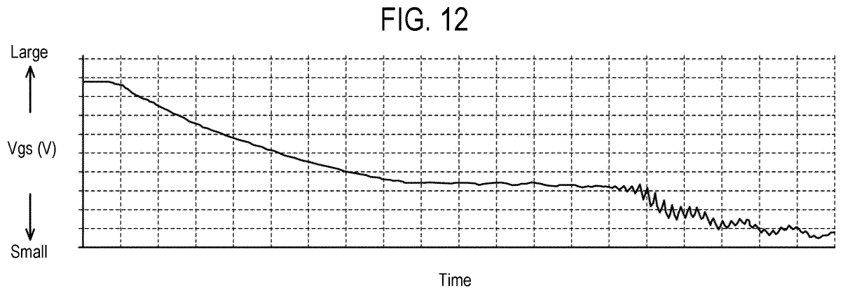

FIG. 12 shows the transition of the gate-source voltage V_{gs} when each of the transistors 11L and 12L is turned off in a case where the ratio (ωₚ₂/ω_{z}) is 0.375. As can be seen from FIG. 12, although the gate-source voltage V_{gs} of the first lower arm transistor 11L oscillates, its amplitude is smaller than that when the ratio (ωₚ₂/ω_{z}) is 0.3 as shown in FIG. 11. For this reason, when the ratio (ωₚ₂/ω_{z}) is 0.375, although parallel oscillation occurs when each of the transistors 11L and 12L is turned off, its amplitude is small. Therefore, when the ratio (ωₚ₂/Oz) is 0.375, it can be said that parallel oscillation is suppressed when each of the transistors 11L and 12L is turned off, as compared to the case where the ratio (ωₚ₂/ω_{z}) is 0.3.

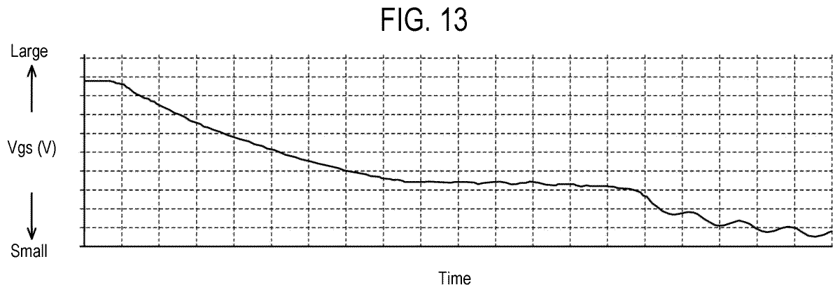

FIG. 13 shows the transition of the gate-source voltage V_{gs} when each of the transistors 11L and 12L is turned off in a case where the ratio (ωₚ₂/ω_{z}) is 0.55. As can be seen from FIG. 13, the gate-source voltage V_{gs} of the first lower arm transistor 11L does not oscillate. For this reason, when the ratio (ωₚ₂/ω_{z}) is 0.55, parallel oscillation does not occur when each of the transistors 11L and 12L is turned off. In this way, in the case where the ratio (ωₚ₂/ω_{z}) is greater than 0.3, parallel oscillation can be suppressed when each of the transistors 11L and 12L is turned off. Note that the parallel oscillation when each of the transistors 11L and 12L is turned off is described in FIGS. 11 to 13, but parallel oscillation can also be suppressed when each of the transistors 11L and 12L is turned on if the ratio (ωₚ₂/ω_{z}) is greater than 0.3.

In this way, by configuring the semiconductor module 10 so that the ratio (ωₚ₂/ω_{z}) is greater than 0.3, the amplitude of parallel oscillation when each of the transistors 11L and 12L is turned off and on can be reduced. Further, by configuring the semiconductor module 10 so that the ratio (ωₚ₂/ω_{z}) is 0.55 or greater, parallel oscillation when each of the transistors 11L and 12L is turned off and on can be suppressed.

In other words, by configuring the semiconductor module 10 so that the absolute value of the phase lag between the second pole frequency ωₚ₂ and the zero frequency ω_{z} is smaller than 180 degrees in the third region R3, parallel oscillation can be suppressed when each of the transistors 11L and 12L is turned off and on.

In the semiconductor module 10, the capacitance ratio (C_{dg}/C_{ds}), gate inductance L_{gg}, drain inductance L_{dd}, and source inductance Lₛₛ of each of the transistors 11U, 12U, 11L and 12L are set so that the absolute value of the phase lag between the second pole frequency ωₚ₂ and the zero frequency ω_{z} is smaller than 180 degrees. That is, in the semiconductor module 10, the absolute value of the phase lag between the second pole frequency ωₚ₂ and the zero frequency ω_{z} can be made smaller than 180 degrees by adjusting at least one selected from the group of the capacitance ratio (C_{dg}/C_{ds}), gate inductance L_{gg}, drain inductance L_{dd}, and source inductance Lₛₛ of each of the transistors 11U, 12U, 11L, and 12L. In an example, in the semiconductor module 10, the absolute value of the phase lag between the second pole frequency ωₚ₂ and the zero frequency ω_{z} can be made smaller than 180° by changing the source inductance Lₛₛ.

In an example, in the semiconductor module 10, the configuration and size of each of the transistors 11U, 12U, 11L, and 12L, the length, diameter, and number of gate wires WGU and WGL, the shape and size of the first power supply wiring 30, the second power supply wiring 40, and the output wiring 50, and the length, diameter, and number of source wires WSU and WSL are determined so that the ratio (ωₚ₂/ω_{z}) is greater than 0.3 or is 0.55 or greater. In other words, in the semiconductor module 10, the ratio (ωₚ₂/ω_{z}) can be made to be greater than 0.3 or to be 0.55 or greater by adjusting at least one selected from the group of the capacitance ratio (C_{dg}/C_{ds}), gate inductance L_{gg}, drain inductance L_{dd}, and source inductance Lₛₛ of each of the transistors 11U, 12U, 11L, and 12L.

As an example, the semiconductor module 10 may be configured so that the ratio (ωₚ₂/ω_{z}) is greater than 0.3 or is 0.55 or greater by changing the source inductance Lₛₛ. Then, in the semiconductor module 10, the diameter, length, and number of source wires WSL are configured so that the ratio (ωₚ₂/ω_{z}) is greater than 0.3 or is 0.55 or greater. The semiconductor module 10 according to the first embodiment includes one source wire WSL, but may include a plurality of source wires so that the ratio (ωₚ₂/ω_{z}) is greater than 0.3 or is 0.55 or greater. In this case, each of the plurality of source wires WSL extends in the X direction. The plurality of source wires WSL are arranged side by side in the Y direction. Here, the X direction is an example of a “first direction.” The Y direction is an example of a “second direction.”

### Effects of First Embodiment

(1-1) The semiconductor module 10 includes the first lower arm transistor 11L and the second lower arm transistor 12L connected in parallel to each other. The parallel resonant circuit of the first lower arm transistor 11L and the second lower arm transistor 12L has the first pole frequency ωₚ₁, the second pole frequency ωₚ₂ higher than the first pole frequency ωₚ₁, and the zero frequency ω_{z}. The absolute value of the phase lag between the second pole frequency ωₚ₂ and the zero frequency ω_{z} is set to be smaller than 180 degrees.

According to this configuration, since the absolute value of the phase lag between the second pole frequency ωₚ₂ and the zero frequency ω_{z} is set to be smaller than 180 degrees, occurrence of parallel oscillation can be suppressed when the first lower arm transistor 11L and the second lower arm transistor 12L are turned on and off.

(1-2) When the parasitic inductance of the conductive path between the first source electrode SL1 of the first lower arm transistor 11L and the second source electrode SL2 of the second lower arm transistor 12L is the source inductance Lₛₛ, the second pole frequency ωₚ₂ is a parameter that changes according to the source inductance Lₛₛ. The source inductance Lₛₛ is set so that the absolute value of the phase lag between the second pole frequency ωₚ₂ and the zero frequency ω_{z} is smaller than 180 degrees.

According to this configuration, by changing the source inductance Lₛₛ, the absolute value of the phase lag between the second pole frequency ωₚ₂ and the zero frequency ω_{z} can be made smaller than 180 degrees. This makes it possible to suppress occurrence of parallel oscillation when the first lower arm transistor 11L and the second lower arm transistor 12L are turned on and off.

(1-3) The ratio (ωₚ₂/ω_{z}) of the second pole frequency ωₚ₂ to the zero frequency ω_{z} is greater than 0.3. According to this configuration, since the semiconductor module 10 is configured so that the ratio (ωₚ₂/ω_{z}) is greater than 0.3, the occurrence of parallel oscillation can be suppressed when the first lower arm transistor 11L and the second lower arm transistor 12L are turned on and off, as compared to when the ratio (ωₚ₂/ω_{z}) is less than 0.3.

(1-4) The ratio (ωₚ₂/ω_{z}) of the second pole frequency ωₚ₂ to the zero frequency ω_{z} is 0.55 or greater. According to this configuration, since the semiconductor module 10 is configured so that the ratio (ωₚ₂/ω_{z}) is 0.55 or greater, the occurrence of parallel oscillation can be reduced to substantially zero when the first lower arm transistor 11L and the second lower arm transistor 12L are turned on and off.

(1-5) The semiconductor module 10 includes the source wire WSL connected to the first source electrode SL1 of the first lower arm transistor 11L and the fourth source electrode SL4 of the second lower arm transistor 12L. The source wire WSL is connected to the first source electrode SL1, the second source electrode SL2, and the second power supply wiring 40 in the length, diameter, and number that satisfy the relationship that the ratio (ωₚ₂/ω_{z}) is greater than 0.3.

According to this configuration, the source inductance Lₛₛ can be easily changed by changing the length, diameter, and number of source wires WSL. Therefore, by changing the length, diameter, and number of source wires WSL, it is easy to adjust the ratio (ωₚ₂/ω_{z}) to be greater than 0.3. This allows the source inductance Lₛₛ to be adjusted so that the ratio (ωₚ₂/ω_{z}) is greater than 0.3 without changing wiring patterns of the second power supply wiring 40, the output wiring 50, and the second gate wiring 62. Therefore, the parallel oscillation of the semiconductor module 10 can be easily suppressed without making significant design changes.

(1-6) The semiconductor module 10 includes the source wire WSL connected to the first source electrode SL1 of the first lower arm transistor 11L and the fourth source electrode SL4 of the second lower arm transistor 12L. The source wire WSL is connected to the first source electrode SL1, the second source electrode SL2, and the second power supply wiring 40 in the length, diameter, and number that satisfy the relationship that the ratio (ωₚ₂/ω_{z}) is 0.55 or greater.

According to this configuration, the source inductance Lₛₛ can be easily changed by changing the length, diameter, and number of the source wire WSL. Therefore, by changing the length, diameter, and number of the source wire WSL, it is easy to adjust the ratio (ωₚ₂/ω_{z}) to be 0.55 or greater. This allows the source inductance Lₛₛ to be adjusted so that the ratio (ωₚ₂/ω_{z}) is 0.55 or greater without changing wiring patterns of the second power supply wiring 40, the output wiring 50, and the second gate wiring 62. Therefore, parallel oscillation of the semiconductor module 10 can be easily suppressed without making significant design changes.

### Second Embodiment

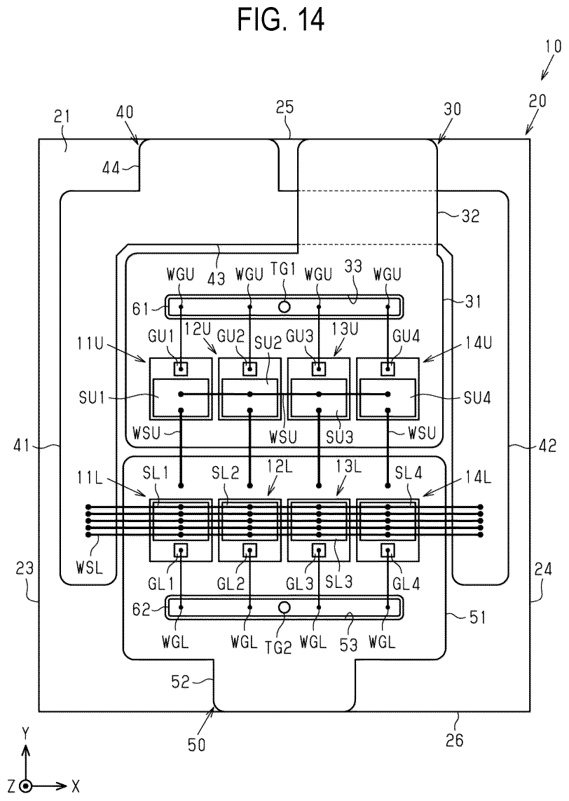

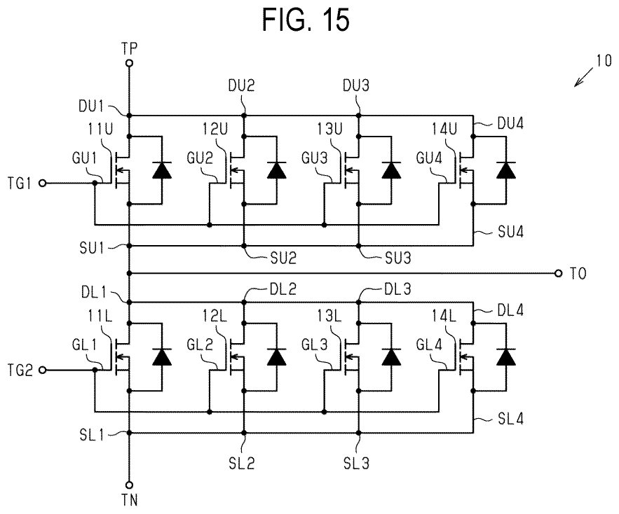

A configuration of a semiconductor module 10 according to a second embodiment will be described with reference to FIGS. 14 and 15. The semiconductor module 10 according to the second embodiment is different from the semiconductor module 10 according to the first embodiment mainly in the number of upper arm transistors and lower arm transistors. In the following, components common to the components of the semiconductor module 10 according to the first embodiment are denoted by the same reference numerals, and explanation thereof will be omitted.

FIG. 14 shows a schematic planar structure of the semiconductor module 10 according to the second embodiment. FIG. 15 shows a schematic circuit configuration of the semiconductor module 10. As shown in FIG. 15, the semiconductor module 10 includes first to fourth upper arm transistors 11U to 14U connected in parallel to each other as an upper arm circuit, and first to fourth lower arm transistors 11L to 14L connected in parallel to each other as a lower arm circuit. Here, in the second embodiment, the first lower arm transistor 11L is an example of a “first transistor,” and the second lower arm transistor 12L or the fourth lower arm transistor 14L is an example of a “second transistor.”

First to fourth drain electrodes DU1 to DU4 of the first to fourth upper arm transistors 11U to 14U are electrically connected to each other and to the power supply terminal TP. First to fourth source electrodes SU1 to SU4 of the first to fourth upper arm transistors 11U to 14U are electrically connected to each other and to the output terminal TO. First to fourth gate electrodes GU1 to GU4 of the first to fourth upper arm transistors 11U to 14U are electrically connected to each other and to the first gate terminal TG1.

First to fourth drain electrodes DL1 to DL4 of the first to fourth lower arm transistors 11L to 14L are electrically connected to each other and to the first to fourth source electrodes SU1 to SU4 of the first to fourth upper arm transistors 11U to 14U. The first to fourth drain electrodes DL1 to DL4 are electrically connected to the output terminal TO. First to fourth source electrodes SL1 to SL4 of the first to fourth lower arm transistors 11L to 14L are electrically connected to each other and to the ground terminal TN. First to fourth gate electrodes GL1 to GL4 of the first to fourth lower arm transistors 11L to 14L are electrically connected to each other and to the second gate terminal TG2.

As shown in FIG. 14, the semiconductor module 10 includes a substrate 20, and a first power supply wiring 30, a second power supply wiring 40, and an output wiring 50 which are provided on a first substrate surface 21 of the substrate 20, similar to the semiconductor module 10 according to the first embodiment (see FIG. 1). Configurations of the substrate 20, the first power supply wiring 30, the second power supply wiring 40, and the output wiring 50 are similar to those of the semiconductor module 10 shown in FIG. 1, and therefore explanation thereof will be omitted.

Herein, the first power supply wiring 30 is an example of a “drain wiring” corresponding to each of the upper arm transistors 11U and 12U, the output wiring 50 is an example of a “source wiring” corresponding to each of the upper arm transistors 11U and 12U, and the first gate wiring 61 is an example of a “gate wiring” corresponding to each of the upper arm transistors 11U and 12U. In addition, the output wiring 50 is an example of a “drain wiring” corresponding to each of the lower arm transistors 11L and 12L, the second power supply wiring 40 is an example of a “source wiring” corresponding to each of the lower arm transistors 11L and 12L, and the second gate wiring 62 is an example of a “gate wiring” corresponding to each of the lower arm transistors 11L and 12L.

The first to fourth upper arm transistors 11U to 14U are mounted on the element mounting portion 31 of the first power supply wiring 30. The first to fourth upper arm transistors 11U to 14U are bonded to the element mounting portion 31 by a conductive bonding material SD, similar to the semiconductor module 10 according to the first embodiment. As a result, the first to fourth drain electrodes DU1 to DU4 of the first to fourth upper arm transistors 11U to 14U are electrically connected to the first power supply wiring 30. The first to fourth upper arm transistors 11U to 14U are disposed at the same position in the Y direction and side by side in the X direction.

The first to fourth gate electrodes GU1 to GU4 of the first to fourth upper arm transistors 11U to 14U are connected to the first gate wiring 61 by a gate wire WGU. The first to fourth source electrodes SU1 to SU4 of the first to fourth upper arm transistors 11U to 14U are connected to each other by a source wire WSU extending in the X direction when viewed from the Z direction. Each of the first to fourth source electrodes SU1 to SU4 is connected to the output wiring 50 by a source wire WSU extending in the Y direction when viewed from the Z direction. As a result, each of the first to fourth source electrodes SU1 to SU4 is electrically connected to the output wiring 50.

The first to fourth lower arm transistors 11L to 14L are mounted on the element mounting portion 51 of the output wiring 50. The first to fourth lower arm transistors 11L to 14L are bonded to the element mounting portion 51 by a conductive bonding material SD, similar to the semiconductor module 10 according to the first embodiment. As a result, the first to fourth drain electrodes DL1 to DL4 of the first to fourth lower arm transistors 11L to 14L are electrically connected to the output wiring 50. Therefore, the first to fourth drain electrodes DL1 to DL4 are electrically connected to the first to fourth source electrodes SU1 to SU4 of the first to fourth upper arm transistors 11U to 14U via the output wiring 50.

The first to fourth gate electrodes GL1 to GL4 of the first to fourth lower arm transistors 11L to 14L are each connected to the second gate wiring 62 by a gate wire WGL. The first to fourth source electrodes SU1 to SU4 of the first to fourth lower arm transistors 11L to 14L are connected to each other and to the first connection wiring 41 and the second connection wiring 42 of the second power supply wiring 40 by a source wire WSL extending in the X direction when viewed from the Z direction. As a result, the first to fourth source electrodes SU1 to SU4 are electrically connected to the second power supply wiring 40. Here, in the second embodiment, the first connection wiring 41 is an example of a “first wiring portion,” and the second connection wiring 42 is an example of a “second wiring portion.”

Similar to the semiconductor module 10 according to the first embodiment, the semiconductor module 10 according to the second embodiment is configured so that the absolute value of the phase lag between the second pole frequency ωₚ₂ and the zero frequency ω_{z} is smaller than 180 degrees. The semiconductor module 10 according to the second embodiment is configured so that the ratio (ωₚ₂/ω_{z}) is greater than 0.3, for example. The semiconductor module 10 according to the second embodiment is configured so that the ratio (ωₚ₂/ω_{z}) is 0.55 or greater, for example.

Similar to the semiconductor module 10 according to the first embodiment, in the semiconductor module 10 according to the second embodiment, the capacitance ratio (C_{dg}/C_{ds}), gate inductance L_{gg}, drain inductance L_{dd}, and source inductance Lₛₛ of each of the transistors 11U to 14U and 11L to 14L are set so that the absolute value of the phase lag between the second pole frequency ωₚ₂ and the zero frequency ω_{z} is smaller than 180 degrees. That is, in the semiconductor module 10 according to the second embodiment, the absolute value of the phase lag between the second pole frequency ωₚ₂ and the zero frequency ω_{z} can be made smaller than 180 degrees by adjusting at least one selected from the group of the capacitance ratio (C_{dg}/C_{ds}), gate inductance L_{gg}, drain inductance L_{dd}, and source inductance Lₛₛ of each of the transistors 11U to 14U and 11L to 14L. In an example, in the semiconductor module 10 according to the second embodiment, the absolute value of the phase lag between the second pole frequency ωₚ₂ and the zero frequency ω_{z} can be made smaller than 180 degrees by changing the source inductance Lₛₛ.

In an example, in the semiconductor module 10 according to the second embodiment, the configuration and size of each of the transistors 11U to 14U, 11L to 14L, the length, diameter, and number of gate wires WGU and WGL, the shape and size of the first power supply wiring 30, the second power supply wiring 40, and the output wiring 50, and the length, diameter, and number of source wires WSU and WSL are determined so that the ratio (ωₚ₂/ω_{z}) is greater than 0.3 or is 0.55 or greater. In other words, in the semiconductor module 10 according to the second embodiment, the ratio (ωₚ₂/ω_{z}) can be made to be greater than 0.3 or to be 0.55 or greater by adjusting at least one selected from the group of the capacitance ratio (C_{dg}/C_{ds}), gate inductance L_{gg}, drain inductance L_{dd}, and source inductance Lₛₛ of each of the transistors 11U to 14U, 11L to 14L.

As an example, similar to the semiconductor module 10 according to the first embodiment, the semiconductor module 10 according to the second embodiment is configured such that the absolute value of the phase lag between the second pole frequency ωₚ₂ and the zero frequency ω_{z} is smaller than 180 degrees by changing the source inductance Lₛₛ. Further, in the semiconductor module 10 according to the second embodiment, the diameter, length, and number of the source wire WSL are configured so that the ratio (ωₚ₂/ω_{z}) is greater than 0.3 or is 0.55 or greater. In the semiconductor module 10 according to the second embodiment, a plurality of source wires WSL are provided so that the ratio (ωₚ₂/ω_{z}) is greater than 0.3 or is 0.55 or greater. In this case, each of the plurality of source wires WSL extends in the X direction. The plurality of source wires WSL are disposed side by side in the Y direction.

<Method of Adjusting Ratio (ωₚ₂/ω_{z})>

Next, an example of a method of adjusting the ratio (ωₚ₂/ω_{z}) will be described by using the semiconductor module 10 according to the second embodiment. As prerequisite conditions, the thickness of each of the second power supply wiring 40, the output wiring 50, and the second gate wiring 62 is 70 m, the capacitance ratio (C_{gd}/C_{ds}) of the first to fourth lower arm transistors 11L to 14L is 0.1, the diameter of the gate wire WGL is 150 m, and the diameter of the source wire WSL is 400 m. The size of each of the first to fourth lower arm transistors 11L to 14L in a plan view is 5×5 mm.

The ratio (ωₚ₂/ω_{z}) is calculated based on the capacitance ratio (C_{gd}/C_{ds}), the gate inductance L_{gg}, the source inductance Lₛₛ, and the drain inductance L_{dd}. Here, since the capacitance ratio (C_{gd}/C_{ds}) is set to 0.1, the ratio (ωₚ₂/ω_{z}) can be adjusted to a desired value by adjusting at least one selected from the group of the gate inductance L_{gg}, the source inductance Lₛₛ, and the drain inductance L_{dd}.

Both of the gate inductance L_{gg} and the source inductance Lₛₛ are calculated by adding up the parasitic inductance of a wire and the parasitic inductance of a wiring pattern. The drain inductance L_{dd} is calculated from the parasitic inductance of the wiring pattern. Here, the parasitic inductance Lw of the wire is calculated by the following equation, and the parasitic inductance Lc of the wiring pattern is calculated by the following equation.

$$Lw \approx 0.2 \times L ( ln \frac{2 L}{a} - 1 ) \qquad [ Eq . 9 ]$$

Note that “L” is a length of the wire, and “a” is a radius of the wire.

$$Lc \approx 0.2 ) \times L \times \{ ln ( \frac{2 \times L}{w + t} ) + 0.2235 \times ( \frac{w + t}{L} ) + 0.5 \} \qquad [ Eq . 10 ]$$

Note that “L” is a length of the wiring pattern, “w” is a width of the wiring pattern, and “t” is a thickness of the wiring pattern. Here, parallel oscillation of the semiconductor module 10 is likely to occur between transistors with a low phase margin among the first to fourth lower arm transistors 11L to 14L. A condition for the low phase margin is that the gate inductance L_{gg} is small or that the source inductance Lₛₛ and the drain inductance L_{dd} are large. The gate inductance L_{gg} is small between adjacent transistors among the first to fourth lower arm transistors 11L to 14L. The source inductance Lₛₛ and the drain inductance L_{dd} are large between the first lower arm transistor 11L and the fourth lower arm transistor 14L.

First, calculation of the gate inductance L_{gg}, drain inductance L_{dd}, and source inductance Lₛₛ between the first lower arm transistor 11L and the second lower arm transistor 12L as the inductances between adjacent transistors among the first to fourth lower arm transistors 11L to 14L will be described.

The gate inductance L_{gg} between the first lower arm transistor 11L and the second lower arm transistor 12L is a sum of the parasitic inductance of both the gate wire WGL connected to the first lower arm transistor 11L and the gate wire WGL connected to the second lower arm transistor 12L, and the parasitic inductance of a portion of the second gate wiring 62 between the two gate wires WGL.

Here, in the semiconductor module 10, a length of the gate wire WGL is 7 mm. A width of the second gate wiring 62 is 2 mm, and a distance between the two gate wires WGL of the second gate wiring 62 is 7 mm.

A parasitic inductance L_{w_gg_1} of one gate wire WGL is calculated from the above equation as follows:

$${L}_{w \_ gg \_ 1} \approx 0.2 \times 7 \times ( ln ( 2 \times 7 / 0.075 ) - 1 ) \approx 5.921 nH / wire .$$

A parasitic inductance L_{c_gg} of the second gate wiring 62 is calculated from the above equation as follows:

$${L}_{c \_ gg} \approx 0.2 \times 7 \times ( ln ( 2 \times 7 ) / ( 2 \times 0.07 ) ) + 0.2235 \times ( 2 + 0.07 ) / 7 + 0.5 \approx 3.469 nH .$$

Therefore, the gate inductance L_{gg} is L_{gg}=5.921×2+3.469=15.311 nH. The drain inductance L_{dd} between the first lower arm transistor 11L and the second lower arm transistor 12L is calculated from a parasitic inductance of a portion of the output wiring 50 between the first lower arm transistor 11L and the second lower arm transistor 12L. The drain inductance L_{dd} is calculated from the above equation as follows:

$${L}_{dd} \approx 0.2 \times 2 \times ( ln ( 2 \times 2 ) / ( 5 \times 0.07 ) ) + 0.2235 \times ( 5 + 0.07 ) / 2 + 0.5 \approx 0.332 nH .$$

Here, a length of the portion of the output wiring 50 between the first lower arm transistor 11L and the second lower arm transistor 12L is 2 mm, and the width thereof is 5 mm. The source inductance Lₛₛ is a sum of the parasitic inductance of the source wire WSL connected to the first lower arm transistor 11L and the source wire WSL connected to the second lower arm transistor 12L, and the parasitic inductance between the above two source wires WSL of the second power supply wiring 40 and the ground terminal TN.

Here, a length of the source wire WSL between the first lower arm transistor 11L and the second lower arm transistor 12L is 7 mm. A total length of a connection portion of the source wire WSL between the first lower arm transistor 11L and the first connection wiring 41 and a connection portion of the source wire WSL between the second lower arm transistor 12L and the second connection wiring 42 is 38 mm. A width (a dimension in the X direction) of each of the first connection wiring 41, second connection wiring 42, and linking wiring 43 of the second power supply wiring 40 is 5 mm, and a length of the second power supply wiring 40 from both ends of the source wire WSL in the X direction to the terminal connection portion 44 is 120 mm.

A parasitic inductance L_{w_ss_1} of the source wire WSL between the first lower arm transistor 11L and the second lower arm transistor 12L is calculated from the above equation as follows:

$${L}_{w \_ ss \_ 1} \approx 0.2 \times 7 \times ( ln ( 2 \times 7 / 0.2 ) - 1 ) \approx 4.548 nH / wire .$$

A total parasitic inductance L_{w_ss_2} of the connection portion of the source wire WSL between the first lower arm transistor 11L and the first connection wiring 41 and the connection portion of the source wire WSL between the second lower arm transistor 12L and the second connection wiring 42 is calculated from the above equation as follows:

$${L}_{w \_ ss \_ 2} \approx 0.2 \times 38 \times ( ln ( 2 \times 38 / 0.2 ) - 1 ) \approx 37.545 nH / wire .$$

The parasitic inductance L_{c_ss} of the second power supply wiring 40 is calculated from the above equation as follows:

$${L}_{c \_ ss} \approx 0.2 \times 120 \times ( ln ( 2 \times 1 \; 20 ) / ( 5 \times 0.07 ) ) + 0.2235 \times ( 5 + 0.07 ) / 120 + 0.5 \approx 104.802 nH .$$

Here, as an example, a method of adjusting the number of source wires WSL in the semiconductor module 10 to set the ratio (ωₚ₂/ω_{z}) to 0.55 or greater will be described. The number of source wires WSL is N (wires). In this case, the parasitic inductance L_{w_ss_1N} of the N source wires WSL between the first lower arm transistor 11L and the second lower arm transistor 12L is L_{w_ss_1N}=4.548/N nH/wire. Further, a total parasitic inductance L_{w_ss_2N} of a connection portion between the first lower arm transistor 11L and the first connection wiring 41 and a connection portion between the second lower arm transistor 12L and the second connection wiring 42 among the N source wires WSL is L_{w_ss_2N}=37.545/N nH/wire. Therefore, a parasitic inductance L_{ssg} of a path electrically connected to the ground terminal TN is L_{ssg}=37.545/N+104.802 nH. Then, since the source inductance Lₛₛ is Lₛₛ=L_{w_ss_1}//L_{ssg},

$${L}_{ss} = 4.548 \times ( 37.545 + 104.8 \; 02 N ) / ( N ( 42.093 + 104.802 N ) ) \approx ( 17 \; 0.755 + 476.639 N ) / ( 42. 093 N + 104.802 {N}^{2} ) .$$

By using these gate inductance L_{gg}, drain inductance L_{dd}, and source inductance Lₛₛ, and the capacitance ratio (C_{gd}/C_{ds})=0.1, the number N of source wires WSL for which the ratio (ωₚ₂/ω_{z})≥0.55 is N≥0.62, using a relational expression for the ratio (ωₚ₂/ω_{z}). In other words, the number of the source wires WSL only needs to be one or more.

Next, the calculation of the gate inductance L_{gg}, drain inductance L_{dd}, and source inductance Lₛₛ between the first lower arm transistor 11L and the fourth lower arm transistor 14L will be described.

The gate inductance L_{gg} between the first lower arm transistor 11L and the fourth lower arm transistor 14L is calculated by a sum of the parasitic inductance of each of the gate wire WGL connected to the first lower arm transistor 11L and the gate wire WGL connected to the fourth lower arm transistor 14L, and the parasitic inductance of the second gate wiring 62 between these gate wires WGL. Here, the length in the X direction between the gate wire WGL connected to the first lower arm transistor 11L and the gate wire WGL connected to the fourth lower arm transistor 14L of the second gate wiring 62 is 21 mm.

As described above, the parasitic inductance L_{w_gg_1} of one gate wire WGL is L_{w_gg_1}≈5.921 nH/wire. The parasitic inductance L_{c_gg} of the second gate wiring 62 is calculated from the above equation as follows:

$${L}_{c \_ gg} \approx 0.2 \times 21 \times ( ln ( 2 \times 21 ) / ( 2 \times 0.07 ) ) + 0.2235 \times ( 2 + 0.07 ) / 21 + 0.5 \approx 14.835 nH .$$

Therefore, the gate inductance L_{gg} is calculated as L_{gg}=5.921×2+14.835=26.677 nH. The drain inductance L_{dd} between the first lower arm transistor 11L and the fourth lower arm transistor 14L is calculated from a parasitic inductance L_{c_dd} of a portion of the output wiring 50 between the first lower arm transistor 11L and the fourth lower arm transistor 14L. Here, the width (dimension in the Y direction) of the portion of the output wiring 50 between the first lower arm transistor 11L and the fourth lower arm transistor 14L is 5 mm, and the length (dimension in the X direction) of the portion of the output wiring 50 between the first lower arm transistor 11L and the fourth lower arm transistor 14L is 16 mm.

As a result, the parasitic inductance L_{c_dd} is L_{c_dd}≈0.2×16×(ln(2×16)/(5×0.07))+0.2235×(5+0.07)/16+0.5≈7.722 nH. Therefore, the drain inductance L_{dd}=7.772 nH.

The source inductance Lₛₛ is a sum of the parasitic inductance of the source wire WSL connected to the first lower arm transistor 11L and the source wire WSL connected to the fourth lower arm transistor 14L, and the parasitic inductance between the above two source wires WSL of the second power supply wiring 40 and the ground terminal TN.

Here, the length of the source wire WSL between the first lower arm transistor 11L and the fourth lower arm transistor 14L is 21 mm. The total length of the connection portion of the source wire WSL between the first lower arm transistor 11L and the first connection wiring 41 and the connection portion between the fourth lower arm transistor 14L and the second connection wiring 42 is 24 mm. The width (dimension in the X direction) of each of the first connection wiring 41, second connection wiring 42, and linking wiring 43 of the second power supply wiring 40 is 5 mm, and the length of the second power supply wiring 40 from both ends of the source wire WSL in the X direction to the terminal connection portion 44 is 120 mm.

The parasitic inductance L_{w_ss_1} of the source wire WSL between the first lower arm transistor 11L and the fourth lower arm transistor 14L is L_{w_ss_1}≈0.2×21×(ln(2×21/0.2)−1)≈18.258 nH/wire.

The total parasitic inductance L_{w_ss_2} of the connection portion of the source wire WSL between the first lower arm transistor 11L and the first connection wiring 41 and the connection portion of the fourth lower arm transistor 14L and the second connection wiring 42 is L_{w_ss_2}≈0.2×24×(ln(2×24/0.2)−1)≈21.507 nH/wire.

The parasitic inductance Lₑ_ss of the second power supply wiring 40 is L_{c_ss}≈0.2×120×(ln(2×120)/(5×0.07))+0.2235×(5+0.07)/120+0.5≈104.802 nH.

Here, in a case where the number of source wires WSL is N, the parasitic inductance L_{w_ss_1N} of the N source wires WSL between the first lower arm transistor 11L and the second lower arm transistor 12L is L_{w_ss_1N}=18.258/N nH/wire. In addition, the total parasitic inductance L_{w_ss_2N} of the connection portion between the first lower arm transistor 11L and the first connection wiring 41 and the connection portion between the fourth lower arm transistor 14L and the second connection wiring 42 among the N source wires WSL is L_{w_ss_2N}=21.507/N nH/wire. Therefore, the parasitic inductance L_{ssg} of the path electrically connected to the ground terminal TN is L_{ssg}=21.507/N+104.802 nH. Further, since the source inductance Lₛₛ is Lₛₛ=L_{w_ss_1}//L_{ssg}, Lₛₛ=18.258×(21.507+104.802N)/(N(39.765+104.802N))≈(392.675+1913.475N)/(39.765N+104.802N²).

By using these gate inductance L_{gg}, drain inductance L_{dd}, and source inductance Lₛₛ, and the capacitance ratio (C_{gd}/C_{ds})=0.1, the number N of source wires WSL for which the ratio (ωₚ₂/ω_{z})≥0.55 is N≥4.16, using the relational expression for the ratio (ωₚ₂/ω_{z}). In other words, the number of the source wires WSL only needs to be five or more.

In this way, the number of source wires WSL for which the ratio (ωₚ₂/ω_{z}) is 0.55 or greater is one based on the parasitic inductance between the first lower arm transistor 11L and the second lower arm transistor 12L, with the condition that the gate inductance L_{gg} is small. In this case, however, parallel oscillation may occur based on the parasitic inductance between the first lower arm transistor 11L and the fourth lower arm transistor 14L. Further, the number of source wires WSL for which the ratio (ωₚ₂/ω_{z}) is 0.55 or greater is five based on the parasitic inductance between the first lower arm transistor 11L and the fourth lower arm transistor 14L, with the condition that the source inductance Lₛₛ and the drain inductance L_{dd} are large. For this reason, in a case where five source wires WSL are provided in the semiconductor module 10, the occurrence of parallel oscillation can be suppressed.

### Effects of Second Embodiment

The semiconductor module 10 according to the second embodiment provides the following effects.

(2-1) The semiconductor module 10 includes the first to fourth lower arm transistors 11L to 14L connected in parallel to each other. The parallel resonant circuit of the first to fourth lower arm transistors 11L to 14L has the first pole frequency ωₚ₁, the second pole frequency ωₚ₂ higher than the first pole frequency ωₚ₁, and the zero frequency ω_{z}. The absolute value of the phase lag between the second pole frequency ωₚ₂ and the zero frequency ω_{z} is set to be smaller than 180 degrees.

According to this configuration, since the semiconductor module 10 is configured so that the absolute value of the phase lag between the second pole frequency ωₚ₂ and the zero frequency ω_{z} is smaller than 180 degrees, the occurrence of parallel oscillation can be suppressed when the first to fourth lower arm transistors 11L to 14L are turned on and off.

(2-2) When the parasitic inductance of the conductive path between the first source electrode SL1 of the first lower arm transistor 11L and the fourth source electrode SL4 of the fourth lower arm transistor 14L is the source inductance Lₛₛ, the second pole frequency ωₚ₂ is a parameter that changes according to the source inductance Lₛₛ. The source inductance Lₛₛ is set so that the absolute value of the phase lag between the second pole frequency ωₚ₂ and the zero frequency ω_{z} is smaller than 180 degrees.

According to this configuration, by changing the source inductance Lₛₛ, the absolute value of the phase lag between the second pole frequency ωₚ₂ and the zero frequency ω_{z} can be made smaller than 180 degrees. This makes it possible to suppress the occurrence of parallel oscillation when the first to fourth lower arm transistors 11L to 14L are turned on and off.

(2-3) The ratio (ωₚ₂/ω_{z}) of the second pole frequency ωₚ₂ to the zero frequency ω_{z} is greater than 0.3. According to this configuration, since the semiconductor module 10 is configured so that the ratio (ωₚ₂/ω_{z}) is greater than 0.3, the occurrence of parallel oscillation can be suppressed when the first to fourth lower arm transistors 11L to 14L are turned on and off, as compared to when the ratio (ωₚ₂/ω_{z}) is smaller than 0.3.

(2-4) The ratio (ωₚ₂/ω_{z}) of the second pole frequency ωₚ₂ to the zero frequency ω_{z} is 0.55 or greater. According to this configuration, since the semiconductor module 10 is configured so that the ratio (ωₚ₂/ω_{z}) is 0.55 or greater, the occurrence of parallel oscillation can be reduced to substantially zero when the first to fourth lower arm transistors 11L to 14L are turned on and off.

(2-5) The semiconductor module 10 includes the plurality of source wires WSL connected to the first to fourth source electrodes SL1 to SL4 of the first to fourth lower arm transistors 11L to 14L. The plurality of source wires WSL have the same length and the same diameter. The plurality of source wires WSL are connected to the first to fourth source electrodes SL1 to SL4 and the second power supply wiring 40 in a number that satisfies the relationship that the ratio (ωₚ₂/ω_{z}) is 0.55 or greater.

According to this configuration, the source inductance Lₛₛ can be easily changed by changing the number of source wires WSL. Therefore, by changing the number of source wires WSL, it is easy to adjust the ratio (ωₚ₂/ω_{z}) to be 0.55 or greater. This allows the source inductance Lₛₛ to be adjusted so that the ratio (ωₚ₂/ω_{z}) is 0.55 or greater without changing the wiring patterns of the second power supply wiring 40, the output wiring 50, and the second gate wiring 62. Therefore, parallel oscillation of the semiconductor module 10 can be easily suppressed without making significant design changes.

(2-6) The lengths of the gate wires WGL individually connected to the first to fourth gate electrodes GL1 to GL4 of the first to fourth lower arm transistors 11L to 14L are equal to each other. According to this configuration, the occurrence of variations in the preset timing of the gate voltages applied to the first to fourth gate electrodes GL1 to GL4 of the first to fourth lower arm transistors 11L to 14L can be suppressed.

### (Application Examples of Semiconductor Module)

The semiconductor module 10 can be applied to inverter devices for vehicles such as electric vehicles, hybrid vehicles, and electrically assisted bicycles. The inverter device may be, for example, an inverter device configured to supply current to a U-phase coil, a V-phase coil, and a W-phase coil of a three-phase brushless motor serving as a driving source. The inverter device includes a U-phase arm part configured to supply a current to the U-phase coil, a V-phase arm part configured to supply a current to the V-phase coil, and a W-phase arm part configured to supply a current to the W-phase coil. Each arm part constitutes, for example, a half-bridge type inverter circuit. The semiconductor module 10 may be applied to each of the U-phase arm part, the V-phase arm part, and the W-phase arm part.

### Modifications

The above-described embodiments can be modified as follows. In addition, the above-described embodiments and the following modifications can be combined with each other as long as they are not technically inconsistent.
In the semiconductor module 10 according to the above-described embodiments, the number of source wires WSL is adjusted to make the ratio (ωₚ₂/ω_{z}) to be 0.55 or greater, but the parameters related to the source wires WSL are not limited to the number. For example, at least one selected from the group of the diameter and the length of the source wire WSL may be changed. In other words, the diameter, length, and number of source wires WSL may be adjusted so that the ratio (ωₚ₂/ω_{z}) is 0.55 or greater.
In the semiconductor module 10 according to the above-described embodiments, the number of source wires WSL is adjusted to make the ratio (ωₚ₂/ω_{z}) to be 0.55 or greater, but the method of adjusting the ratio (ωₚ₂/ω_{z}) is not limited to the source wire WSL. For example, the ratio (ωₚ₂/ω_{z}) may be made to be 0.55 or greater by changing the shape and size of the second power supply wiring 40. In addition, the ratio (ωₚ₂/ω_{z}) is not limited to the adjustment of the source inductance Lₛₛ, and at least one selected from the group of the gate inductance L_{gg} and the drain inductance L_{dd} may be adjusted.
In the semiconductor module 10 according to the above-described embodiments, when a plurality of source wires WSL are provided, the diameters of the plurality of source wires WSL may be different from one another.
In the semiconductor module 10 according to the above-described embodiments, when a plurality of source wires WSL are provided, the lengths of the plurality of source wires WSL may be different from one another.
In the semiconductor module 10 according to the above-described embodiments, when a plurality of source wires WSU connected to the first to fourth upper arm transistors 11U to 14U are provided, the diameters of the plurality of source wires WSU may be different from one another.
In the semiconductor module 10 according to the above-described embodiments, when a plurality of source wires WSU are provided, the lengths of the plurality of source wires WSU may be different from one another.
In the semiconductor module 10 according to the above-described embodiments, the length of the gate wire WGL connected to the first lower arm transistor 11L and the length of the gate wire WGL connected to the second lower arm transistor 12L may be different from each other. The length of the gate wire WGL connected to the first lower arm transistor 11L and the length of the gate wire WGL connected to the fourth lower arm transistor 14L may be different from each other. The lengths of the gate wires WGL connected to the first to fourth lower arm transistors 11L to 14L may be different from one another.
In the semiconductor module 10 according to the above-described embodiments, the diameters of the gate wires WGL connected to the first to fourth lower arm transistors 11L to 14L may be different from one another.
In the semiconductor module 10 according to the above-described embodiments, the diameters of the gate wires WGU connected to the first to fourth upper arm transistors 11U to 14U may be different from one another.
In the semiconductor module 10 according to the above-described embodiments, the lengths of the gate wires WGU connected to the first to fourth upper arm transistors 11U to 14U may be different from one another.
In the semiconductor module 10 according to the above-described embodiments, the capacitance ratio (C_{gd}/C_{ds}) is set to 0.1 when calculating the ratio (ωₚ₂/ω_{z}), but it is not limited thereto. For example, the parasitic capacitance C_{gd} between the gate and drain of each of the first to fourth lower arm transistors 11L to 14L may be changed to change the zero frequency ω_{z}. In this case, the parasitic capacitance C_{gd} is set so that the absolute value of the phase lag between the second pole frequency ωₚ₂ and the zero frequency ω_{z} is smaller than 180 degrees.
In the semiconductor module 10 according to the above-described embodiments, the number of source wires WSL is set so that the ratio (ωₚ₂/ω_{z}) is 0.55 or greater, but it is not limited thereto. In an example, the number of source wires WSL may be set so that the ratio (ωₚ₂/ω_{z}) is greater than 0.3. In this case, the lengths of the plurality of source wires WSL are equal to one another, and the diameters of the plurality of source wires WSL are equal to one another. In an example, the diameter, length, and number of source wires WSL may be set so that the ratio (ωₚ₂/ω_{z}) is greater than 0.3.
In the semiconductor module 10 according to the above-described embodiments, the gate inductance L_{gg}, source inductance Lₛₛ, and drain inductance L_{dd} of each of the first to fourth upper arm transistors 11U to 14U may be adjusted so that the ratio (ωₚ₂/ω_{z}) is 0.55 or greater. In an example, the number of source wires WSU of the first to fourth upper arm transistors 11U to 14U may be changed so that the ratio (ωₚ₂/ω_{z}) is 0.55 or greater. In this case, the lengths of the plurality of source wires WSU are equal to one another, and the diameters of the plurality of source wires WSU are equal to one another. In another example, the diameter, length, and number of source wires WSU may be set so that the ratio (ωₚ₂/ω_{z}) is 0.55 or greater.
In the semiconductor module 10 according to the above-described embodiments, the gate inductance L_{gg}, source inductance Lₛₛ, and drain inductance L_{dd} of each of the first to fourth upper arm transistors 11U to 14U may be adjusted so that the ratio (ωₚ₂/ω_{z}) is greater than 0.3. In an example, the number of source wires WSU of each of the first to fourth upper arm transistors 11U to 14U may be changed so that the ratio (ωₚ₂/ω_{z}) is greater than 0.3. In this case, the lengths of the plurality of source wires WSU are equal to one another, and the diameters of the plurality of source wires WSU are equal to one another. In another example, the diameter, length, and number of source wires WSU may be set so that the ratio (ωₚ₂/ω_{z}) is greater than 0.3.
In the semiconductor module 10 according to the above-described embodiments, the ratio (ωₚ₂/ω_{z}) may be smaller than 1. That is, the ratio (ωₚ₂/ω_{z}) may be greater than 0.3 and smaller than 1 (0.3<(ωₚ₂/ω_{z})<1). In addition, the ratio (ωₚ₂/ω_{z}) may be 0.55 or greater and smaller than 1≤(0.55 (ωₚ₂/ω_{z})<1). In addition, in the semiconductor module 10, the ratio (ωₚ₂/co) may be greater than 1.
In the semiconductor module 10 according to the above-described embodiments, the source connection member that connects the first source electrode SU1 of the first upper arm transistor 11U and the second source electrode SU2 of the second upper arm transistor 12U is not limited to the source wire WSU. For example, the source connection member may be a ribbon, a clip, or a bus bar instead of the source wire WSU. Similarly, the source connection member that connects the third source electrode SU3 of the third upper arm transistor 13U and the fourth source electrode SU4 of the fourth upper arm transistor 14U may be a ribbon, a clip, or a bus bar instead of the source wire WSU. In this way, the source connection member may be any member capable of electrically connecting the first to fourth source electrodes SU1 to SU4.

In this case, in an example, the source connection members may be connected to the first source electrode SU1, the second source electrode SU2 (or any one of the second source electrodes SU2 to SU4), and the output wiring 50 in a size and number that satisfy the relationship that the ratio (ωₚ₂/ω_{z}) of the second pole frequency ωₚ₂ to the zero frequency ω_{z} is greater than 0.3. In another example, the source connection members may be connected to the first source electrode SU1, the second source electrode SU2 (or any one of the second source electrodes SU2 to SU4), and the output wiring 50 in a size and number that satisfy the relationship that the ratio (ωₚ₂/ω_{z}) of the second pole frequency ωₚ₂ to the zero frequency ω_{z} is 0.55 or greater. Here, the size of each source connection member may be, for example, the length, width, and thickness of the source connection member. The sizes of the plurality of source connection members may be the same or may be different from one another. In an example, in a case where the plurality of source connection members are of the same size, the plurality of source connection members may be connected to the first source electrode SU1, the second source electrode SU2 (or any one of the second source electrodes SU2 to SU4), and the output wiring 50 in a number that satisfies the relationship that the ratio (ωₚ₂/ω_{z}) of the second pole frequency ωₚ₂ to the zero frequency ω_{z} is greater than 0.3. In another example, in a case where the plurality of source connection members are of the same size, the source connection members may be connected to the first source electrode SU1, the second source electrode SU2 (or any one of the second source electrodes SU2 to SU4), and the output wiring 50 in a number that satisfies the relationship that the ratio (ωₚ₂/ω_{z}) of the second pole frequency ωₚ₂ to the zero frequency ω_{z} is 0.55 or greater.
In the semiconductor module 10 according to the above-described embodiments, the source connection member that connects the first source electrode SL1 of the first lower arm transistor 11L and the second source electrode SL2 of the second lower arm transistor 12L is not limited to the source wire WSL. For example, the source connection member may be a ribbon, a clip, or a bus bar instead of the source wire WSL. Similarly, the source connection member that connects the third source electrode SL3 of the third lower arm transistor 13L and the fourth source electrode SL4 of the fourth lower arm transistor 14L may be a ribbon, a clip, or a bus bar instead of the source wire WSL. In this way, the source connection member may be any member capable of electrically connecting the first to fourth source electrodes SL1 to SL4.

In this case, in an example, the source connection members may be connected to the first source electrode SL1, the second source electrode SL2 (or any one of the second source electrodes SL2 to SL4), and the second power supply wiring 40 in a size and a number that satisfy the relationship that the ratio (ωₚ₂/ω_{z}) of the second pole frequency ωₚ₂ to the zero frequency ω_{z} is greater than 0.3. In another example, the source connection members may be connected to the first source electrode SL1, the second source electrode SL2 (or any one of the second source electrodes SL2 to SL4), and the second power supply wiring 40 in a size and a number that satisfy the relationship that the ratio (ωₚ₂/ω_{z}) of the second pole frequency ωₚ₂ to the zero frequency ω_{z} is 0.55 or greater. Here, the size of each source connection member may be, for example, the length, width, and thickness of the source connection member. The sizes of the plurality of source connection members may be the same as each other or may be different from each other. In an example, in a case where the plurality of source connection members are of the same size, the plurality of source connection members may be connected to the first source electrode SL1, the second source electrode SL2 (or any one of the second source electrodes SL2 to SL4), and the second power supply wiring 40 in a number that satisfies the relationship that the ratio (ωₚ₂/ω_{z}) of the second pole frequency ωₚ₂ to the zero frequency ω_{z} is greater than 0.3. In another example, in a case where the plurality of source connection members are of the same size, the plurality of source connection members may be connected to the first source electrode SL1, the second source electrode SL2 (or any one of the second source electrodes SL2 to SL4), and the second power supply wiring 40 in a number that satisfies the relationship that the ratio (ωₚ₂/ω_{z}) of the second pole frequency ωₚ₂ to the zero frequency ω_{z} is 0.55 or greater.
In the semiconductor module 10 according to the above-described embodiments, the number of lower arm transistors may be changed arbitrarily. In an example, the number of lower arm transistors may be six. In another example, the number of lower arm transistors may be eight.
In the semiconductor module 10 according to the above-described embodiments, the number of upper arm transistors may be changed arbitrarily. In an example, the number of upper arm transistors may be six. In another example, the number of upper arm transistors may be eight.

One or more of the various examples described in the present disclosure may be combined as long as they are not technically inconsistent. The term “on” as used in the present disclosure includes meanings of “on” and “above” unless clearly stated otherwise in the context. Therefore, the expression “a first element is disposed on a second element,” for example, is intended that in some embodiments, the first element may be directly disposed on the second element in contact with the second element, while in other embodiments, the first element may be disposed above the second element without contacting the second element. That is, the term “on” does not exclude a structure in which other elements are formed between the first and second elements.

The Z direction used in the present disclosure does not have to be a vertical direction, and it does not have to be exactly the same as the vertical direction. Therefore, in various structures according to the present disclosure, “up” and “down” in the Z-axis direction described herein are not limited to being “up” and “down” in the vertical direction. For example, the X-axis direction may be the vertical direction, or the Y-axis direction may be the vertical direction.

### Supplementary Notes

The technical concepts that can be grasped from the above-described embodiments are described below. In addition, for the purpose of aiding understanding and not for the purpose of limitation, components described in supplementary notes are labeled with the reference numerals of the corresponding components in the above-described embodiments. The reference numerals are provided as examples to aid understanding, and the components described in supplementary notes should not be limited to the components indicated by the reference numerals.

### Supplementary Note 1

A semiconductor module (10) including:
a first transistor (11L/11U) and a second transistor (12L, 12L to 14L/12U, 12U to 14U) connected in parallel to each other,
wherein a parallel resonant circuit of the first transistor (11L/11U) and the second transistor (12L, 12L to 14L/12U, 12U to 14U) has:
a first pole frequency (ωₚ₁);
a second pole frequency (ωₚ₂) higher than the first pole frequency (ωₚ₁); and
a zero frequency (ωz), and
wherein an absolute value of a phase lag between the second pole frequency (ωₚ₂) and the zero frequency (ωz) is set to be smaller than 180 degrees.

### Supplementary Note 2

The semiconductor module of Supplementary Note 1, wherein, when a parasitic inductance of a conductive path between a first source electrode (SL1/SU1) of the first transistor (11L/11U) and a second source electrode (SL2, SL2 to SL4/SU2, SU2 to SU4) of the second transistor (12L, 12L to 14L/12U, 12U to 14U) is Lₛₛ, the second pole frequency (ωₚ₂) is a parameter that changes according to the parasitic inductance Lₛₛ, and the parasitic inductance Lₛₛ is set so that the absolute value of the phase lag between the second pole frequency (ωₚ₂) and the zero frequency (ωz) is smaller than 180 degrees.

### Supplementary Note 3

The semiconductor module of Supplementary Note 1, wherein, when a parasitic capacitance between a gate and a drain of the first transistor (11L/11U) or the second transistor (12L, 12L to 14L/12U, 12U to 14U) is C_{gd}, the zero frequency (ωz) is a parameter that changes according to the parasitic capacitance C_{gd}, and the parasitic capacitance C_{gd} is set so that the absolute value of the phase lag between the second pole frequency (ωₚ₂) and the zero frequency (coz) is smaller than 180 degrees.

### Supplementary Note 4

The semiconductor module of any one of Supplementary Notes 1 to 3, wherein a ratio (ωₚ₂/ω_{z}) of the second pole frequency (ωₚ₂) to the zero frequency (ω_{z}) is greater than 0.3.

### Supplementary Note 5

The semiconductor module of any one of Supplementary Notes 1 to 3, wherein a ratio (ωₚ₂/ω_{z}) of the second pole frequency (ωₚ₂) to the zero frequency (ω_{z}) is 0.55 or greater.

### Supplementary Note 6

The semiconductor module of Supplementary Note 2, wherein the first transistor (11L/11U) includes a first gate electrode (GL1/GU1), a first drain electrode (DL1/DU1), and the first source electrode (SL1/SU1),
wherein the second transistor (12L, 12L to 14L/12U, 12U to 14U) includes a second gate electrode (GL2, GL2 to GL4/GU2, GU2 to GU4), a second drain electrode (DL2, DL2 to DL4/DU2, DU2 to DU4), and the second source electrode (SL2, SL2 to SL4/SU2, SU2 to SU4), and
wherein the semiconductor module further includes:
a drain wiring (50/30) to which the first drain electrode (DL1/DU1) and the second drain electrode (DL2, DL2 to DL4/DU2, DU2 to DU4) are electrically connected;
a source wiring (40/50) disposed to be spaced apart from the drain wiring (50/30) and electrically connected to the first source electrode (SL1/SU1) and the second source electrode (SL2, SL2 to SL4/SU2, SU2 to SU4);
a gate wiring (62/61) disposed to be spaced apart from both of the drain wiring (50/30) and the source wiring (40/50) and electrically connected to the first gate electrode (GL1/GU1) and the second gate electrode (GL2, GL2 to GL4/GU1, GU2 to GU4);
at least one source connection member (WSL/WSU) connecting the first source electrode (SL1/SU1), the second source electrode (SL2, SL2 to SL4/SU2, SU2 to SU4), and the source wiring (40/50);
a first gate connection member (WGL/WGU) connecting the first gate electrode (GL1/GU1) and the gate wiring (62/61); and
a second gate connection member (WGL/WGU) connecting the second gate electrode (GL2, GL2 to GL4/GU2, GU2 to GU4) and the gate wiring (62/61).

### Supplementary Note 7

The semiconductor module of Supplementary Note 6, wherein the at least one source connection member is connected to the first source electrode (SL1/SU1), the second source electrode (SL2, SL2 to SL4/SU2, SU2 to SU4), and the source wiring (40/50) in a size and a number that satisfy a relationship that a ratio (ωₚ₂/ω_{z}) of the second pole frequency (ωₚ₂) to the zero frequency (ω_{z}) is greater than 0.3.

### Supplementary Note 8

The semiconductor module of Supplementary Note 6, wherein the at least one source connection member is a source wire (WSL/WSU) and is connected to the first source electrode (SL1/SU1), the second source electrode (SL2, SL2 to SL4/SU2, SU2 to SU4), and the source wiring (40/50) in a diameter, a length, and a number that satisfy a relationship that a ratio (ωₚ₂/ω_{z}) of the second pole frequency (ωₚ₂) to the zero frequency (ω_{z}) is greater than 0.3.

### Supplementary Note 9

The semiconductor module of Supplementary Note 6, wherein the at least one source connection member is connected to the first source electrode (SL1/SU1), the second source electrode (SL2, SL2 to SL4/SU2, SU2 to SU4), and the source wiring (40/50) in a size and a number that satisfy a relationship that a ratio (ωₚ₂/ω_{z}) of the second pole frequency (ωₚ₂) to the zero frequency (ω_{z}) is 0.55 or greater.

### Supplementary Note 10

The semiconductor module of Supplementary Note 6, wherein the at least one source connection member is a source wire (WSL/WSU) and is connected to the first source electrode (SL1/SU1), the second source electrode (SL2, SL2 to SL4/SU2, SU2 to SU4), and the source wiring (40/50) in a diameter, a length, and a number that satisfy a relationship that a ratio (ωₚ₂/ω_{z}) of the second pole frequency (ωₚ₂) to the zero frequency (ω_{z}) is 0.55 or greater.

### Supplementary Note 11

The semiconductor module of Supplementary Note 6, wherein the at least one source connection member includes a plurality of source connection members of a same size, and
wherein the plurality of source connection members are connected to the first source electrode (SL1/SU1), the second source electrode (SL2, SL2 to SL4/SU2, SU2 to SU4), and the source wiring (40/50) in a number that satisfies a relationship that a ratio (ωₚ₂/ω_{z}) of the second pole frequency (ωₚ₂) to the zero frequency (ω_{z}) is greater than 0.3.

### Supplementary Note 12

The semiconductor module of Supplementary Note 6, wherein the at least one source connection member includes a plurality of source connection members of a same size, and
wherein the plurality of source connection member are connected to the first source electrode (SL1/SU1), the second source electrode (SL2, SL2 to SL4/SU2, SU2 to SU4), and the source wiring (40/50) in a number that satisfies a relationship that a ratio (ωₚ₂/ω_{z}) of the second pole frequency (ωₚ₂) to the zero frequency (ω_{z}) is 0.55 or greater.

### Supplementary Note 13

The semiconductor module of Supplementary Note 6, wherein the at least one source connection member includes a plurality of source wires (WSL/WSU) of a same diameter and length, and
wherein the plurality of source wires (WSL/WSU) are connected to the first source electrode (SL1/SU1), the second source electrode (SL2, SL2 to SL4/SU2, SU2 to SU4), and the source wiring (40/50) in a number that satisfies a relationship that a ratio (ωₚ₂/ω_{z}) of the second pole frequency (ωₚ₂) to the zero frequency (ω_{z}) is greater than 0.3.

### Supplementary Note 14

The semiconductor module of Supplementary Note 6, wherein the at least one source connection member includes a plurality of source wires (WSL/WSU) of a same diameter and length, and
wherein the plurality of source wires (WSL/WSU) are connected to the first source electrode (SL1/SU1), the second source electrode (SL2, SL2 to SL4/SU2, SU2 to SU4), and the source wiring (40/50) in a number that satisfies a relationship that a ratio (ωₚ₂/ω_{z}) of the second pole frequency (ωₚ₂) to the zero frequency (ω_{z}) is 0.55 or greater.

### Supplementary Note 15

The semiconductor module of Supplementary Note 13 or 14, wherein each of the plurality of source wires (WSL) extends in a first direction (X) in a plan view, and
wherein the plurality of source wires (WSL) are disposed side by side in a second direction (Y) perpendicular to the first direction (X) in a plan view.

### Supplementary Note 16

The semiconductor module of any one of Supplementary Notes 6 to 15, wherein the first transistor (11L) and the second transistor (12L, 12L to 14L) are disposed to be spaced apart from each other in a first direction (X),
wherein the source wiring (40) includes:
a first wiring portion (41) disposed on one side of the first transistor (11L) and the second transistor (12L, 12L to 14L) in the first direction (X); and
a second wiring portion (42) disposed on the other side of the first transistor (11L) and the second transistor (12L, 12L to 14L) in the first direction (X), and
wherein the at least one source connection member (WSL) extends in the first direction (X) in a plan view and is connected to the first source electrode (SL1), the second source electrode (SL2, SL2 to SL4), the first wiring portion (41), and the second wiring portion (42).

### Supplementary Note 17

The semiconductor module of any one of Supplementary Notes 6 to 16, wherein a length of the first gate connection member (WGL/WGU) is equal to a length of the second gate connection member (WGL/WGU).

### Supplementary Note 18

The semiconductor module of any one of Supplementary Notes 7 to 15, wherein the ratio (ωₚ₂/co) of the second pole frequency (ωₚ₂) to the zero frequency (ω_{z}) is smaller than 1.

### Supplementary Note 19

The semiconductor module of Supplementary Note 6, wherein a ratio (ωₚ₂/ω_{z}) of the second pole frequency (ωₚ₂) to the zero frequency (ω_{z}) is greater than 1.

### Supplementary Note 20

A semiconductor module (10) including:
a first transistor (11L/11U) and a second transistor (12L, 12L to 14L/12U, 12U to 14U) connected in parallel to each other,
wherein a parallel resonant circuit of the first transistor (11L/11U) and the second transistor (12L, 12L to 14L/12U, 12U to 14U) has:
a first pole frequency (ωₚ₁);
a second pole frequency (ωₚ₂) higher than the first pole frequency (ωₚ₁); and
a zero frequency (ω_{z}), and
wherein a ratio (ωₚ₂/ω_{z}) of the second pole frequency (ωₚ₂) to the zero frequency (ω_{z}) is greater than 0.3.

### Supplementary Note 21

The semiconductor module of Supplementary Note 20, wherein the first transistor (11L/12U) includes a first gate electrode (GL1/GU1), a first source electrode (SL1/SU1), and a first drain electrode (DL1/DU1), and the second transistor (12L, 12L to 14L/12U, 12U to 14U) includes a second gate electrode (GL2, GL2 to GL4/GU2, GU2 to GU4), a second source electrode (SL2, SL2 to SL4/SU2, SU2 to SU4), and a second drain electrode (DL2, DL2 to DL4/DU2, DU2 to DU4), and
wherein the semiconductor module further includes:
a drain wiring (50/30) to which the first drain electrode (DL1/DU1) and the second drain electrode (DL2, DL2 to DL4/DU2, DU2 to DU4) are electrically connected;
a source wiring (40/50) disposed to be spaced apart from the drain wiring (50/30) and electrically connected to the first source electrode (SL1/SU1) and the second source electrode (SL2, SL2 to SL4/SU2, SU2 to SU4);
a gate wiring (62/61) disposed to be spaced apart from both of the drain wiring (50/30) and the source wiring (40/50) and electrically connected to the first gate electrode (GL1/GU1) and the second gate electrode (GL2, GL2 to GL4/GU2, GU2 to GU4);
at least one source connection member (WSL/WSU) connecting the first source electrode (SL1/SU1), the second source electrode (SL2, SL2 to SL4/SU2, SU2 to SU4), and the source wiring (40/50);
a first gate connection member (WGL/WGU) connecting the first gate electrode (GL1/GU1) and the gate wiring (62/61); and
a second gate connection member (WGL/WGU) connecting the second gate electrode (GL2, GL2 to GL4/GU2, GU2 to GU4) and the gate wiring (62/61).

### Supplementary Note 22

The semiconductor module of Supplementary Note 21, wherein the at least one source connection member is connected to the first source electrode (SL1/SU1), the second source electrode (SL2, SL2 to SL4/SU2, SU2 to SU4), and the source wiring (40/50) in a size and a number that satisfy a relationship that the ratio (ωₚ₂/ω_{z}) of the second pole frequency (ωₚ₂) to the zero frequency (ω_{z}) is greater than 0.3.

### Supplementary Note 23

The semiconductor module of Supplementary Note 21, wherein the at least one source connection member is a source wire (WSL/WSU) and is connected to the first source electrode (SL1/SU1), the second source electrode (SL2, SL2 to SL4/SU2, SU2 to SU4), and the source wiring (40/50) in a diameter, a length, and a number that satisfy a relationship that the ratio (ωₚ₂/ω_{z}) of the second pole frequency (ωₚ₂) to the zero frequency (ω_{z}) is greater than 0.3.

### Supplementary Note 24

The semiconductor module of Supplementary Note 21, wherein the at least one source connection member includes a plurality of source connection members of the same size, and
wherein the plurality of source connection members are connected to the first source electrode (SL1/SU1), the second source electrode (SL2, SL2 to SL4/SU2, SU2 to SU4), and the source wiring (40/50) in a number that satisfies a relationship that the ratio (ωₚ₂/ω_{z}) of the second pole frequency (ωₚ₂) to the zero frequency (ω_{z}) is greater than 0.3.

### Supplementary Note 25

The semiconductor module of Supplementary Note 21, wherein the at least one source connection member includes a plurality of source wires (WSL/WSU) of the same diameter and length, and
wherein the plurality of source wires (WSL/WSU) are connected to the first source electrode (SL1/SU1), the second source electrode (SL2, SL2 to SL4/SU2, SU2 to SU4), and the source wiring (40/50) in a number that satisfies a relationship that a ratio (ωₚ₂/ω_{z}) of the second pole frequency (ωₚ₂) to the zero frequency (ω_{z}) is greater than 0.3.

### Supplementary Note 26

The semiconductor module of Supplementary Note 25, wherein each of the plurality of source wires (WSL) extends in a first direction (X) in a plan view, and
wherein the plurality of source wires (WSL) are disposed side by side in a second direction (Y) perpendicular to the first direction (X) in a plan view.

### Supplementary Note 27

The semiconductor module of any one of Supplementary Notes 21 to 26, wherein the first transistor (11L) and the second transistor (12L, 12L to 14L) are disposed to be spaced apart from each other in a first direction (X),
wherein the source wiring (40) includes:
a first wiring portion (41) disposed on one side of the first transistor (11L) and the second transistor (12L, 12L to 14L) in the first direction (X); and
a second wiring portion (42) disposed on the other side of the first transistor (11L) and the second transistor (12L, 12L to 14L) in the first direction (X), and
wherein the at least one source connection member (WSL) extends in the first direction (X) in a plan view and is connected to the first source electrode (SL1), the second source electrode (SL2, SL2 to SL4), the first wiring portion (41), and the second wiring portion (42).

### Supplementary Note 28

The semiconductor module of any one of Supplementary Notes 21 to 27, wherein a length of the first gate connection member (WGL/WGU) is equal to a length of the second gate connection member (WGL/WGU).

### Supplementary Note 29

The semiconductor module of Supplementary Note 21, wherein the ratio (ωₚ₂/ω_{z}) of the second pole frequency (ωₚ₂) to the zero frequency (ω_{z}) is smaller than 1.

### Supplementary Note 30

The semiconductor module of Supplementary Note 21, wherein the ratio (ωₚ₂/ω_{z}) of the second pole frequency (ωₚ₂) to the zero frequency (ω_{z}) is greater than 1.

### Supplementary Note 31

A semiconductor module (10) including:
a first transistor (11L/11U) and a second transistor (12L, 12L to 14L/12U, 12U to 14U) connected in parallel to each other,
wherein a parallel resonant circuit of the first transistor (11L/11U) and the second transistor (12L, 12L to 14L/12U, 12U to 14U) has:
a first pole frequency (ωₚ₁);
a second pole frequency (ωₚ₂) higher than the first pole frequency (ωₚ₁); and
a zero frequency (ω_{z}), and
wherein a ratio (ωₚ₂/ω_{z}) of the second pole frequency (ωₚ₂) to the zero frequency (ω_{z}) is 0.55 or greater.

### Supplementary Note 32

The semiconductor module of Supplementary Note 31, wherein the first transistor (11L/12U) includes a first gate electrode (GL1/GU1), a first source electrode (SL1/SU1), and a first drain electrode (DL1/DU1), and the second transistor (12L, 12L to 14L/12U, 12U to 14U) includes a second gate electrode (GL2, GL2 to GL4/GU2, GU2 to GU4), a second source electrode (SL2, SL2 to SL4/SU2, SU2 to SU4), and a second drain electrode (DL2, DL2 to DL4/DU2, DU2 to DU4),
wherein the semiconductor module further includes:
a drain wiring (50/30) to which the first drain electrode (DL1/DU1) and electrically connected to the second drain electrode (DL2, DL2 to DL4/DU2, DU2 to DU4);
a source wiring (40/50) disposed to be spaced apart from the drain wiring (50/30) and electrically connected to the first source electrode (SL1/SU1) and the second source electrode (SL2, SL2 to SL4/SU2, SU2 to SU4);
a gate wiring (62/61) disposed to be spaced apart from both of the drain wiring (50/30) and the source wiring (40/50) and electrically connected to the first gate electrode (GL1/GU1) and the second gate electrode (GL2, GL2 to GL4/GU2, GU2 to GU4);
at least one source connection member (WSL/WSU) connecting the first source electrode (SL1/SU1), the second source electrode (SL2, SL2 to SL4/SU2, SU2 to SU4), and the source wiring (40/50);
a first gate connection member (WGL) connecting the first gate electrode (GL1/GU1) and the gate wiring (62/61); and
a second gate connection member (WGL/WGU) connecting the second gate electrode (GL2, GL2 to GL4/GU2, GU2 to GU4) and the gate wiring (62/61).

### Supplementary Note 33

The semiconductor module of Supplementary Note 32, wherein the at least one source connection member is connected to the first source electrode (SL1/SU1), the second source electrode (SL2, SL2 to SL4/SU2, SU2 to SU4), and the source wiring (40/50) in a size and a number that satisfy a relationship that the ratio (ωₚ₂/ω_{z}) of the second pole frequency (ωₚ₂) to the zero frequency (ω_{z}) is 0.55 or greater.

### Supplementary Note 34

The semiconductor module of Supplementary Note 32, wherein the at least one source connection member is a source wire (WSL/WSU) and is connected to the first source electrode (SL1/SU1), the second source electrode (SL2, SL2 to SL4/SU2, SU2 to SU4), and the source wiring (40/50) in a diameter, a length, and a number that satisfy a relationship that the ratio (ωₚ₂/ω_{z}) of the second pole frequency (ωₚ₂) to the zero frequency (ω_{z}) is 0.55 or greater.

### Supplementary Note 35

The semiconductor module of Supplementary Note 32, wherein the at least one source connection member includes a plurality of source connection members of the same size, and
wherein the plurality of source connection members are connected to the first source electrode (SL1/SU1), the second source electrode (SL2, SL2 to SL4/SU2, SU2 to SU4), and the source wiring (40/50) in a number that satisfies a relationship that the ratio (ωₚ₂/ω_{z}) of the second pole frequency (ωₚ₂) to the zero frequency (ω_{z}) is 0.55 or greater.

### Supplementary Note 36

The semiconductor module of Supplementary Note 32, wherein the at least one source connection member includes a plurality of source wires (WSL) of the same diameter and length, and
wherein the plurality of source wires (WSL) are connected to the first source electrode (SL1/SU1), the second source electrode (SL2, SL2 to SL4/SU2, SU2 to SU4), and the source wiring (40/50) in a number that satisfies a relationship that the ratio (ωₚ₂/ω_{z}) of the second pole frequency (ωₚ₂) to the zero frequency (ω_{z}) is 0.55 or greater.

### Supplementary Note 37

The semiconductor module of Supplementary Note 36, wherein each of the plurality of source wires (WSL) extends in a first direction (X) in a plan view, and
wherein the plurality of source wires (WSL) are disposed side by side in a second direction (Y) perpendicular to the first direction (X) in a plan view.

### Supplementary Note 38

The semiconductor module of any one of Supplementary Notes 32 to 37, wherein the first transistor (11L) and the second transistor (12L, 12L to 14L) are disposed to be spaced apart from each other in a first direction (X),
wherein the source wiring (40) includes:
a first wiring portion (41) disposed on one side of the first transistor (11L) and the second transistor (12L, 12L to 14L) in the first direction (X); and
a second wiring portion (42) disposed on the other side of the first transistor (11L) and the second transistor (12L, 12L to 14L) in the first direction (X), and
wherein the at least one source connection member (WSL) extends in the first direction (X) in a plan view and is connected to the first source electrode (SL1), the second source electrode (SL2, SL2 to SL4), the first wiring portion (41), and the second wiring portion (42).

### Supplementary Note 39

The semiconductor module of any one of Supplementary Notes 32 to 38, wherein a length of the first gate connection member (WGL/WGU) is equal to a length of the second gate connection member (WGL/WGU).

### Supplementary Note 40

The semiconductor module of Supplementary Note 31, wherein the ratio (ωₚ₂/ω_{z}) of the second pole frequency (ωₚ₂) to the zero frequency (ω_{z}) is smaller than 1.

### Supplementary Note 41

The semiconductor module of Supplementary Note 31, wherein the ratio (ωₚ₂/ω_{z}) of the second pole frequency (ωₚ₂) to the zero frequency (ω_{z}) is greater than 1.

The above description is merely an example. Those skilled in the art will appreciate that more conceivable combinations and substitutions are possible as well as the components and methods (manufacturing processes) listed for the purposes of illustrating the techniques of the present disclosure. The present disclosure is intended to cover all alternatives, modifications, and changes that fall within the scope of the present disclosure, including the claims.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor module comprising:
a first transistor and a second transistor connected in parallel to each other,
wherein a parallel resonant circuit of the first transistor and the second transistor has:
a first pole frequency (ωₚ₁);
a second pole frequency (ωₚ₂) higher than the first pole frequency (ωₚ₁); and
a zero frequency (ω_{z}), and
wherein an absolute value of a phase lag between the second pole frequency (ωₚ₂) and the zero frequency (ω_{z}) is set to be smaller than 180 degrees.

2. The semiconductor module of claim 1, wherein, when a parasitic inductance of a conductive path between a first source electrode of the first transistor and a second source electrode of the second transistor is Lₛₛ, the second pole frequency (ωₚ₂) is a parameter that changes according to the parasitic inductance (Lₛₛ), and the parasitic inductance (Lₛₛ) is set so that the absolute value of the phase lag between the second pole frequency (ωₚ₂) and the zero frequency (ω_{z}) is smaller than 180 degrees.

3. The semiconductor module of claim 1, wherein, when a parasitic capacitance between a gate and a drain of the first transistor or the second transistor is C_{gd}, the zero frequency (ω_{z}) is a parameter that changes according to the parasitic capacitance (C_{gd}), and the parasitic capacitance (C_{gd}) is set so that the absolute value of the phase lag between the second pole frequency (ωₚ₂) and the zero frequency (ω_{z}) is smaller than 180 degrees.

4. The semiconductor module of claim 1, wherein a ratio (ωₚ₂/ω_{z}) of the second pole frequency (ωₚ₂) to the zero frequency (ω_{z}) is greater than 0.3.

5. The semiconductor module of claim 1, wherein a ratio (ωₚ₂/ω_{z}) of the second pole frequency (ωₚ₂) to the zero frequency (ω_{z}) is 0.55 or greater.

6. The semiconductor module of claim 2, wherein the first transistor includes a first gate electrode, a first drain electrode, and the first source electrode,
wherein the second transistor includes a second gate electrode, a second drain electrode, and the second source electrode, and
wherein the semiconductor module further comprises:
a drain wiring to which the first drain electrode and the second drain electrode are electrically connected;
a source wiring disposed to be spaced apart from the drain wiring and electrically connected to the first source electrode and the second source electrode;
a gate wiring disposed to be spaced apart from both of the drain wiring and the source wiring and electrically connected to the first gate electrode and the second gate electrode;
at least one source connection member connecting the first source electrode, the second source electrode, and the source wiring;
a first gate connection member connecting the first gate electrode and the gate wiring; and
a second gate connection member connecting the second gate electrode and the gate wiring.

7. The semiconductor module of claim 6, wherein the at least one source connection member is connected to the first source electrode, the second source electrode, and the source wiring in a size and a number that satisfy a relationship that a ratio (ωₚ₂/ω_{z}) of the second pole frequency (ωₚ₂) to the zero frequency (ω_{z}) is greater than 0.3.

8. The semiconductor module of claim 6, wherein the at least one source connection member is a source wire and is connected to the first source electrode, the second source electrode, and the source wiring in a diameter, a length, and a number that satisfy a relationship that a ratio (ωₚ₂/ω_{z}) of the second pole frequency (ωₚ₂) to the zero frequency (ω_{z}) is greater than 0.3.

9. The semiconductor module of claim 6, wherein the at least one source connection member is connected to the first source electrode, the second source electrode, and the source wiring in a size and a number that satisfy a relationship that a ratio (ωₚ₂/ω_{z}) of the second pole frequency (ωₚ₂) to the zero frequency (ω_{z}) is 0.55 or greater.

10. The semiconductor module of claim 6, wherein the at least one source connection member is a source wire and is connected to the first source electrode, the second source electrode, and the source wiring in a diameter, a length, and a number that satisfy a relationship that a ratio (ωₚ₂/ω_{z}) of the second pole frequency (ωₚ₂) to the zero frequency (ω_{z}) is 0.55 or greater.

11. The semiconductor module of claim 6, wherein the at least one source connection member includes a plurality of source connection members of a same size, and
wherein the plurality of source connection members are connected to the first source electrode, the second source electrode, and the source wiring in a number that satisfies a relationship that a ratio (ωₚ₂/ω_{z}) of the second pole frequency (ωₚ₂) to the zero frequency (ω_{z}) is greater than 0.3.

12. The semiconductor module of claim 6, wherein the at least one source connection member includes a plurality of source connection members of a same size, and
wherein the plurality of source connection members are connected to the first source electrode, the second source electrode, and the source wiring in a number that satisfies a relationship that a ratio (ωₚ₂/ω_{z}) of the second pole frequency (ωₚ₂) to the zero frequency (ω_{z}) is 0.55 or greater.

13. The semiconductor module of claim 6, wherein the at least one source connection member includes a plurality of source wires of a same diameter and a same length, and
wherein the plurality of source wires are connected to the first source electrode, the second source electrode, and the source wiring in a number that satisfies a relationship that a ratio (ωₚ₂/ω_{z}) of the second pole frequency (ωₚ₂) to the zero frequency (ω_{z}) is greater than 0.3.

14. The semiconductor module of claim 6, wherein the at least one source connection member includes a plurality of source wires of a same diameter and a same length, and
wherein the plurality of source wires are connected to the first source electrode, the second source electrode, and the source wiring in a number that satisfies a relationship that a ratio (ωₚ₂/ω_{z}) of the second pole frequency (ωₚ₂) to the zero frequency (ω_{z}) is 0.55 or greater.

15. The semiconductor module of claim 13, wherein each of the plurality of source wires extends in a first direction in a plan view, and
wherein the plurality of source wires are disposed side by side in a second direction perpendicular to the first direction in a plan view.

16. The semiconductor module of claim 6, wherein the first transistor and the second transistor are disposed to be spaced apart from each other in a first direction,
wherein the source wiring includes:
a first wiring portion disposed on one side of the first transistor and the second transistor in the first direction; and
a second wiring portion disposed on the other side of the first transistor and the second transistor in the first direction, and
wherein the at least one source connection member extends in the first direction in a plan view and is connected to the first source electrode, the second source electrode, the first wiring portion, and the second wiring portion.

17. The semiconductor module of claim 6, wherein a length of the first gate connection member is equal to a length of the second gate connection member.
